(19) United States
(12) Patent Application Publication
(10) Pub. No.: US 2025/0237951 A1
(43) Pub. Date: Jul. 24, 2025

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM CORPORATION, Tokyo (JP)

(72) Inventors: Kotaro Takahashi, Shizuoka (JP); Yuka Kamino, Shizuoka (JP)

(21) Appl. No.: 19/176,620

(22) Filed: Apr. 11, 2025

Related U.S. Application Data
(63) Continuation of application No. PCT/JP2023/036196, filed on Oct. 4, 2023.

(30) Foreign Application Priority Data
Oct. 14, 2022 (JP) 2022-165373

(51) Int. Cl. G03F 7/039; G03F 7/004

(52) U.S. Cl. CPC G03F 7/0397; G03F 7/0045

(57) ABSTRACT

An actinic ray-sensitive or radiation-sensitive resin composition including a resin (A) including an acid-decomposable group and a phenolic hydroxyl group, a resin (B) which does not include an acid-decomposable group, an acid generator (C), and an acid diffusion control agent (D), wherein the resin (B) includes a repeating unit (b1) having a hydrophilic group and a fluorine atom, the hydrophilic group and the fluorine atom in the repeating unit (b1) are covalently bonded to a main chain of the resin (B), or are covalently bonded to a side chain which is covalently bonded to the main chain of the resin (B), and the resin (B) does not include an ammonium salt structure; an actinic ray-sensitive or radiation-sensitive film formed using the actinic ray-sensitive or radiation-sensitive resin composition; a pattern forming method; and a method for producing an electronic device.

### CROSS REFERENCE TO RELATED APPLICATION

This is a continuation of International Application No. PCT/JP2023/036196 filed on Oct. 4, 2023, and claims priority from Japanese Patent Application No. 2022-165373 filed on Oct. 14, 2022, the entire disclosure of which is incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device. More specifically, the present invention relates to an actinic ray-sensitive or radiation-sensitive resin composition that can be suitably used in ultramicrolithography processes applicable to, for example, processes for producing ultra-LSIs (Large Scale Integrations) and high-capacity microchips, processes for producing nanoimprint molds, and processes for producing high-density information recording media, and other photofabrication processes, an actinic ray-sensitive or radiation-sensitive film, a pattern forming method, and a method for producing an electronic device.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

In addition, currently, lithography using, instead of excimer laser beams, an electron beam (EB), X-rays, extreme ultraviolet rays (EUV), or the like is also being developed. With this, resist compositions effectively sensitive to various actinic rays or radiations have been developed.

For example, JP2022-19584A, JP2018-45152A, and JP2014-34638A describe resist compositions containing acid-decomposable resins, acid generators, acid diffusion control agents, additive polymers, and the like.

### SUMMARY OF THE INVENTION

In recent years, there has been an increasing demand for higher performance for resist compositions. In particular, there has been a demand for an increase in the resolution during formation of an ultrafine pattern (for example, a trench pattern having a width of 15 nm or less).

Thus, an object of the present invention is to provide an actinic ray-sensitive or radiation-sensitive resin composition that provides high resolution, an actinic ray-sensitive or radiation-sensitive film formed using the actinic ray-sensitive or radiation-sensitive resin composition, a pattern forming method using the actinic ray-sensitive or radiation-sensitive resin composition, and a method for producing an electronic device.

The inventors of the present invention have found that the following features can address the above-described object.
[1]

An actinic ray-sensitive or radiation-sensitive resin composition containing:
a resin (A) including an acid-decomposable group and a phenolic hydroxyl group;
a resin (B) which does not include an acid-decomposable group;
an acid generator (C); and
an acid diffusion control agent (D),
wherein the resin (B) includes a repeating unit (b1) having a hydrophilic group and a fluorine atom,
the hydrophilic group and the fluorine atom in the repeating unit (b1) are covalently bonded to a main chain of the resin (B), or are covalently bonded to a side chain which is covalently bonded to the main chain of the resin (B), and
the resin (B) does not include an ammonium salt structure.
[2]

The actinic ray-sensitive or radiation-sensitive resin composition according to [1], wherein a total amount of the acid generator (C) relative to a total solid content of the actinic ray-sensitive or radiation-sensitive resin composition is 0.40 mmol/g or more and 1.50 mmol/g or less.
[3]

The actinic ray-sensitive or radiation-sensitive resin composition according to [1] or [2], wherein Qp, which is a value obtained by dividing a total substance amount of the acid diffusion control agent (D) included in the actinic ray-sensitive or radiation-sensitive resin composition by a total substance amount of cations included in the actinic ray-sensitive or radiation-sensitive resin composition, is 0.40 or more and 1.00 or less.
[4]

The actinic ray-sensitive or radiation-sensitive resin composition according to any one of [1] to [3], wherein a sum of values obtained by multiplying C log P of each repeating unit included in the resin (B) by a molar fraction of the each repeating unit included in the resin (B) is 0 or less.
[5]

The actinic ray-sensitive or radiation-sensitive resin composition according to any one of [1] to [4], wherein a distance Ra between Hansen solubility parameters of the resin (B) and Hansen solubility parameters of air is 35 MPa^{0.5} or less.
[6]

The actinic ray-sensitive or radiation-sensitive resin composition according to any one of [1] to [5], wherein a sum of values obtained by multiplying a value obtained by dividing a number of fluorine atoms in each repeating unit included in the resin (B) by a number of all atoms included in the resin (B), by a molar fraction of the each repeating unit included in the resin (B) is 10 mol % or more.
[7]

The actinic ray-sensitive or radiation-sensitive resin composition according to any one of [1] to [6], wherein W_{B}/Qp, which is a value obtained by dividing a mass-based content ratio W_{B} of the resin (B) included in the actinic ray-sensitive or radiation-sensitive resin composition by Qp, which is a value obtained by dividing a total substance amount of the acid diffusion control agent (D) included in the actinic ray-sensitive or radiation-sensitive resin composition by a total substance amount of cations included in the actinic ray-sensitive or radiation-sensitive resin composition, is less than 20 mass %.
[8]

The actinic ray-sensitive or radiation-sensitive resin composition according to any one of [1] to [7], wherein the repeating unit (b1) is a repeating unit represented by a formula (T1) below:

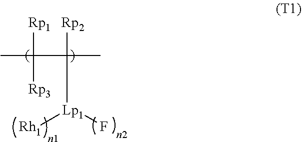

in the formula (T1), Rp₁ to Rp₃ each independently represent a hydrogen atom, an alkyl group, a cycloalkyl group, a halogen atom, a cyano group, or an alkoxycarbonyl group;
Lp₁ represents a linking group;
Rh₁ represents a hydrophilic group;
n1 and n2 each independently represent an integer of 1 or more;
when a plurality of Rh₁ are present, the plurality of Rh₁ may be the same or different; and two selected from the group consisting of Rp₁ to Rp₃ and Lp₁ may be bonded together to form a ring.
[9]

The actinic ray-sensitive or radiation-sensitive resin composition according to [8], wherein the repeating unit represented by the formula (T1) is a repeating unit represented by any one of formulas (T2) to (T4) below:

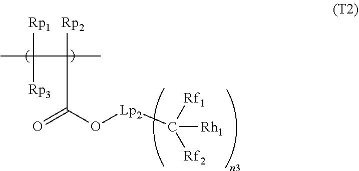

in the formula (T2), Rp₁ to Rp₃ and Rh₁ respectively have the same meanings as Rp₁ to Rp₃ and Rh₁ in the formula (T1);
Lp₂ represents a linking group which is at least one selected from the group consisting of an alkylene group, a cycloalkylene group, and an arylene group;
Rf₁ and Rf₂ each independently represent a fluorine atom or a fluorinated alkyl group;
n3 represents an integer of 1 or more;
when a plurality of Rh₁, Rf₁, and Rf₂ are present, the plurality of Rh₁, Rf₁, and Rf₂ may be individually the same or different; and
two selected from the group consisting of Rp₁ to Rp₃ may be bonded together to form a ring,

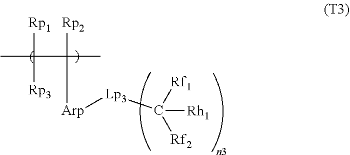

in the formula (T3), Rp₁ to Rp₃ and Rh₁ respectively have the same meanings as Rp₁ to Rp₃ and Rh₁ in the formula (T1);
Arp represents an arylene group;
Lp₃ represents a linking group which is at least one selected from the group consisting of an alkylene group, a cycloalkylene group, —O—, and —CO—, or a single bond;
Rf₁ and Rf₂ each independently represent a fluorine atom or a fluorinated alkyl group;
n3 represents an integer of 1 or more;
when a plurality of Rh₁, Rf₁, and Rf₂ are present, the plurality of Rh₁, Rf₁, and Rf₂ may be individually the same or different; and
two selected from the group consisting of Rp₁ to Rp₃, Arp, and Lp₃ may be bonded together to form a ring,

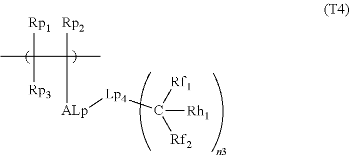

in the formula (T4), Rp₁ to Rp₃ and Rh₁ respectively have the same meanings as Rp₁ to Rp₃ and Rh₁ in the formula (T1);
ALp represents a linking group which is at least one selected from the group consisting of an alkylene group and a cycloalkylene group;
Lp₄ represents a linking group which is at least one selected from the group consisting of an arylene group, —O—, and —CO—, or a single bond;
Rf₁ and Rf₂ each independently represent a fluorine atom or a fluorinated alkyl group;
n3 represents an integer of 1 or more;
when a plurality of Rh₁, Rf₁, and Rf₂ are present, the plurality of Rh₁, Rf₁, and Rf₂ may be individually the same or different; and
two selected from the group consisting of Rp₁ to Rp₃, ALp, and Lp₄ may be bonded together to form a ring.
[10]

The actinic ray-sensitive or radiation-sensitive resin composition according to any one of [1] to [9], wherein the resin (A) includes at least one repeating unit selected from the group consisting of a repeating unit represented by a formula (S1) below and a repeating unit represented by a formula (S2) below:

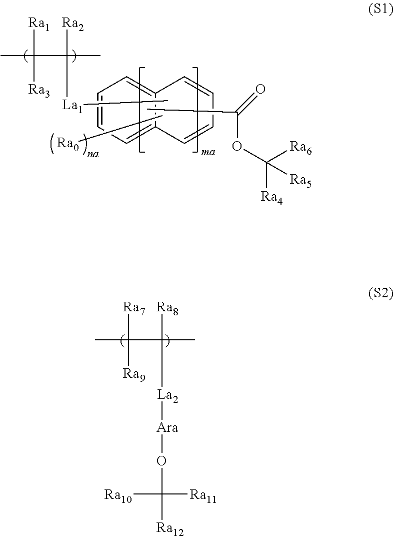

in the formula (S1), Ra₁ to Ra₃ each independently represent a hydrogen atom, an alkyl group, a cycloalkyl group, a halogen atom, a cyano group, or an alkoxycarbonyl group;
La₁ represents a single bond or a divalent linking group;
Ra₄ to Ra₆ each independently represent a hydrogen atom, an alkyl group, a cycloalkyl group, an aryl group, an aromatic heterocyclic group, an aralkyl group, or an alkenyl group;
two selected from the group consisting of Ra₄ to Ra₆ may be bonded together to form a ring;
Ra₀ represents a substituent; when a plurality of Ra₀ are present, the plurality of Ra₀ may be the same or different;
two selected from the group consisting of Ra₁ to Ra₃, La₁, and Ra₀ may be bonded together to form a ring;
na represents an integer of 0 to 4; and
ma represents an integer of 0 to 2,
in the formula (S2), Ra₇ to Ra₉ each independently represent a hydrogen atom, an alkyl group, a cycloalkyl group, a halogen atom, a cyano group, or an alkoxycarbonyl group;
La₂ represents a single bond or a divalent linking group;
Ara represents an aromatic ring group;
Ra₁₀ to Ra₁₂ each independently represent a hydrogen atom, an alkyl group, a cycloalkyl group, an aryl group, an aromatic heterocyclic group, an aralkyl group, an alkoxy group, a cycloalkyloxy group, or an alkenyl group;
at least two selected from the group consisting of Ra₁₀ to Ra₁₂ may be bonded together to form a ring; and
at least one selected from the group consisting of Ra₉ to Ra₁₂ may be bonded to Ara.
[11]

The actinic ray-sensitive or radiation-sensitive resin composition according to any one of [1] to [10], wherein the resin (A) includes a repeating unit represented by a formula (S3) below:

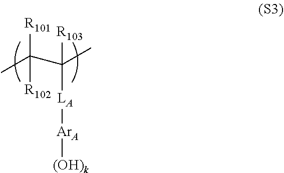

in the formula (S3), R₁₀₁, R₁₀₂, and R₁₀₃ each independently represent a hydrogen atom, an alkyl group, a cycloalkyl group, a halogen atom, a cyano group, or an alkoxycarbonyl group; R₁₀₂ may be bonded to Ar_{A} to form a ring and, in this case, R₁₀₂ represents a single bond or an alkylene group;
L_{A} represents a single bond or a divalent linking group;
Ar_{A} represents an aromatic ring group; and
k represents an integer of 1 to 5.
[12]

An actinic ray-sensitive or radiation-sensitive film formed by using the actinic ray-sensitive or radiation-sensitive resin composition according to any one of [1] to [11].
[13]

A pattern forming method including:
resist film formation of using the actinic ray-sensitive or radiation-sensitive resin composition according to any one of [1] to [11] to form a resist film;
exposure of exposing the resist film; and
development of developing the exposed resist film using a developer.
[14]

A method for producing an electronic device, the method including the pattern forming method according to [13].

The present invention can provide an actinic ray-sensitive or radiation-sensitive resin composition that provides high resolution, an actinic ray-sensitive or radiation-sensitive film formed using the actinic ray-sensitive or radiation-sensitive resin composition, a pattern forming method using the actinic ray-sensitive or radiation-sensitive resin composition, and a method for producing an electronic device.

### DESCRIPTION OF THE PREFERRED EMBODIMENTS

Hereinafter, the present invention will be described in detail.

In the following descriptions, features may be described on the basis of representative embodiments of the present invention; however, the present invention is not limited to such embodiments.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, soft X-rays, or an electron beam (EB: Electron Beam).

In this Specification, “light” means an actinic ray or a radiation.

In this Specification, “exposure” includes, unless otherwise specified, not only exposure using the emission line spectrum of a mercury lamp, far-ultraviolet rays represented by excimer lasers, extreme ultraviolet rays, X-rays, EUV, or the like, but also pattern exposure using a corpuscular beam such as an electron beam or an ion beam.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (Mw/Mn) are defined as polystyrene-equivalent values determined, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M, manufactured by Tosoh Corporation, column temperature: 40° C., flow rate: 1.0 mL/min, detector: differential refractive index detector (Refractive Index Detector)).

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified. Examples of the substituent include monovalent non-metallic atomic groups except for the hydrogen atom and, for example, can be selected from the group consisting of the following Substituents T.

### Substituents T

Examples of the substituents T include halogen atoms such as a fluorine atom, a chlorine atom, a bromine atom, and an iodine atom; alkoxy groups such as a methoxy group, an ethoxy group, and a tert-butoxy group; cycloalkyloxy groups; aryloxy groups such as a phenoxy group and a p-tolyloxy group; alkoxycarbonyl groups such as a methoxycarbonyl group and a butoxycarbonyl group; cycloalkyloxycarbonyl groups; aryloxycarbonyl groups such as a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; a sulfanyl group; alkylsulfanyl groups such as a methylsulfanyl group and a tert-butylsulfanyl group; arylsulfanyl groups such as a phenylsulfanyl group and a p-tolylsulfanyl group; alkyl groups; alkenyl groups; cycloalkyl groups; aryl groups; aromatic heterocyclic groups; a hydroxy group; a carboxyl group; a formyl group; a sulfo group; a cyano group; alkylaminocarbonyl groups; arylaminocarbonyl groups; a sulfonamide group; a silyl group; an amino group; and a carbamoyl group. When such a substituent can additionally have one or more substituents, a group having, as the additional substituents, one or more substituents selected from the group consisting of the substituents described above (such as a monoalkylamino group, a dialkylamino group, an arylamino group, or a trifluoromethyl group) is also included in examples of the substituents T.

In this Specification, the bonding directions of divalent groups described are not limited unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H⁺ dissociation free energy in an aqueous solution based on a thermodynamic cycle. The H⁺ dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density function theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

In this Specification, “solid content” means components forming the actinic ray-sensitive or radiation-sensitive film and does not include solvents. As long as a component forms the actinic ray-sensitive or radiation-sensitive film, even when the component has the form of liquid, it is regarded as the solid content.

### Actinic Ray-Sensitive or Radiation-Sensitive Resin Composition

An actinic ray-sensitive or radiation-sensitive resin composition of the present invention (also referred to as “the composition of the present invention”) is an actinic ray-sensitive or radiation-sensitive resin composition containing a resin (A) including an acid-decomposable group and a phenolic hydroxyl group, a resin (B) not including an acid-decomposable group, an acid generator (C), and an acid diffusion control agent (D), wherein the resin (B) includes a repeating unit (b1) having a hydrophilic group and a fluorine atom, the hydrophilic group and the fluorine atom in the repeating unit (b1) are covalently bonded to a main chain of the resin (B) or covalently bonded to a side chain covalently bonded to the main chain of the resin (B), and the resin (B) does not include an ammonium salt structure.

The composition of the present invention is typically a resist composition, and may be a positive resist composition or may be a negative resist composition. The composition of the present invention may be a resist composition for alkali development or may be a resist composition for organic-solvent development.

The composition of the present invention may be a chemical amplification resist composition or may be a non-chemical amplification resist composition. The composition of the present invention is typically a chemical amplification resist composition.

The composition of the present invention can be used to form an actinic ray-sensitive or radiation-sensitive film. The actinic ray-sensitive or radiation-sensitive film formed using the composition of the present invention is typically a resist film.

Hereinafter, first, components of the composition of the present invention will be described in detail.

### Resin (A)

The resin (A) included in the composition of the present invention is a resin including an acid-decomposable group and a phenolic hydroxyl group.

The resin (A) is an acid-decomposable resin and, in a pattern forming method using the composition of the present invention, typically, in a case of employing a developer that is an alkali developer, a positive-type pattern is suitably formed or, in another case of employing a developer that is an organic-based developer, a negative-type pattern is suitably formed.

The resin (A) preferably includes a repeating unit having an acid-decomposable group and a repeating unit having a phenolic hydroxyl group. The repeating unit having an acid-decomposable group and the repeating unit having a phenolic hydroxyl group are preferably repeating units different from each other.

The acid-decomposable group is a group that is decomposed by the action of an acid to provide increased polarity, and is typically a group that is decomposed by the action of an acid to generate a polar group. The acid-decomposable group preferably has a structure in which a polar group is protected with a group (leaving group) that leaves by the action of an acid. Typically, in the resin (A), the action of the acid increases the polarity to cause an increase in the degree of solubility in the alkali developer but to cause a decrease in the degree of solubility in organic solvents.

The acid-decomposable group is preferably a group that is decomposed by the action of an acid to generate a polar group.

The polar group is preferably an alkali-soluble group, and examples thereof include acidic groups such as a carboxy group, a phenolic hydroxyl group, fluorinated alcohol groups, a sulfonic acid group, a phosphoric acid group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and alcoholic hydroxyl groups.

Examples of the leaving group that leaves by the action of an acid include groups represented by formulas (Y1) to (Y4).

—C(Rx₁)(Rx₂)(Rx₃) Formula (Y1)

—C(═O)OC(Rx₁)(Rx₂)(Rx₃) Formula (Y2)

—C(R₃₆)(R₃₇)(OR₃₈) Formula (Y3)

—C(Rn)(H)(Ar) Formula (Y4)

In the formula (Y1) and the formula (Y2), Rx₁ to Rx₃ each independently represent an alkyl group (linear or branched), a cycloalkyl group (monocyclic or polycyclic), an aryl group (monocyclic or polycyclic), an aralkyl group (linear or branched), or an alkenyl group (linear or branched). Note that, when all of Rx₁ to Rx₃ are alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two of Rx₁ to Rx₃ may be bonded together to form a ring (which may be either monocyclic or polycyclic).

For Rx₁ to Rx₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms, and examples thereof include a phenyl group, a naphthyl group, and an anthryl group.

For Rx₁ to Rx₃, the aralkyl group is preferably a group in which one hydrogen atom in the above-described alkyl group for Rx₁ to Rx₃ is substituted with an aryl group having 6 to 10 carbon atoms (preferably a phenyl group), and examples thereof include a benzyl group.

For Rx₁ to Rx₃, the alkenyl group is preferably a vinyl group.

The ring formed by bonding together two of Rx₁ to Rx₃ is preferably a cycloalkyl group. The cycloalkyl group formed by bonding together two of Rx₁ to Rx₃ is preferably a monocyclic cycloalkyl group such as a cyclopentyl group or a cyclohexyl group, and a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two of Rx₁ to Rx₃, for example, one of the methylene groups constituting the ring may be replaced by a heteroatom such as an oxygen atom, a group having a heteroatom such as a carbonyl group, or a vinylidene group. In the cycloalkyl group, one or more of the ethylene groups constituting the cycloalkane ring may be replaced by vinylene groups.

The group represented by the formula (Y1) or the formula (Y2) preferably has a form in which, for example, Rx₁ is a methyl group or an ethyl group, and Rx₂ and Rx₃ are bonded together to form the above-described cycloalkyl group.

In the formula (Y3), R₃₆ to R₃₈ each independently represent a hydrogen atom or a monovalent organic group. R₃₇ and R₃₈ may be bonded together to form a ring. Examples of the monovalent organic group include alkyl groups, cycloalkyl groups, aryl groups, aralkyl groups, and alkenyl groups. R₃₆ is also preferably a hydrogen atom.

Note that the alkyl groups, cycloalkyl groups, aryl groups, and aralkyl groups may include a heteroatom such as an oxygen atom and/or a group having a heteroatom such as a carbonyl group. For example, in the alkyl groups, cycloalkyl groups, aryl groups, and aralkyl groups, for example, one or more methylene groups may be replaced by a heteroatom such as an oxygen atom and/or a group having a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

In the formula (Y4), Ar represents an aromatic ring group. Rn represents an alkyl group, a cycloalkyl group, or an aryl group. Rn and Ar may be bonded together to form a non-aromatic ring. Ar is more preferably an aryl group.

The resin (A) preferably includes at least one repeating unit selected from the group consisting of a repeating unit represented by the following formula (S1) and a repeating unit represented by the following formula (S2). The repeating unit represented by the following formula (S1) and the repeating unit represented by the following formula (S2) are preferably repeating units having an acid-decomposable group.

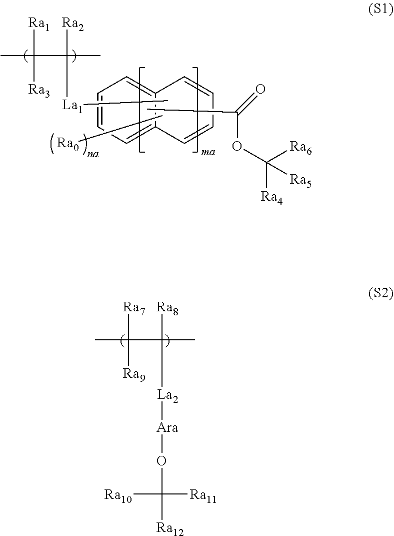

In the formula (S1), Ra₁ to Ra₃ each independently represent a hydrogen atom, an alkyl group, a cycloalkyl group, a halogen atom, a cyano group, or an alkoxycarbonyl group. La₁ represents a single bond or a divalent linking group. Ra₄ to Ra₆ each independently represent a hydrogen atom, an alkyl group, a cycloalkyl group, an aryl group, an aromatic heterocyclic group, an aralkyl group, or an alkenyl group. Two of Ra₄ to Ra₆ may be bonded together to form a ring. Ra₀ represents a substituent. When a plurality of Ra₀ are present, the plurality of Ra₀ may be the same or different. Two of Ra₁ to Ra₃, La₁, and Ra₀ may be bonded together to form a ring. na represents an integer of 0 to 4. ma represents an integer of 0 to 2.

In the formula (S2), Ra₇ to Ra₉ each independently represent a hydrogen atom, an alkyl group, a cycloalkyl group, a halogen atom, a cyano group, or an alkoxycarbonyl group. La₂ represents a single bond or a divalent linking group. Ara represents an aromatic ring group. Ra₁₀ to Ra₁₂ each independently represent a hydrogen atom, an alkyl group, a cycloalkyl group, an aryl group, an aromatic heterocyclic group, an aralkyl group, an alkoxy group, a cycloalkyloxy group, or an alkenyl group. At least two of Ra₁₀ to Ra₁₂ may be bonded together to form a ring. At least one of Ra₉ to Ra₁₂ may be bonded to Ara.

### Repeating Unit Represented by Formula (S1)

In the formula (S1), Ra₁ to Ra₃ each independently represent a hydrogen atom, an alkyl group, a cycloalkyl group, a halogen atom, a cyano group, or an alkoxycarbonyl group.

For Ra₁ to Ra₃, the alkyl group may be either linear or branched. The number of carbon atoms of the alkyl group is not particularly limited, but is preferably 1 to 5, and more preferably 1 to 3.

For Ra₁ to Ra₃, the number of carbon atoms of the cycloalkyl group is not particularly limited, but is preferably 3 to 20, and more preferably 5 to 15. For Ra₁ to Ra₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ra₁ to Ra₃, the halogen atom may be a fluorine atom, a chlorine atom, a bromine atom, or an iodine atom, and preferred is a fluorine atom or an iodine atom.

For Ra₁ to Ra₃, the alkyl group included in the alkoxycarbonyl group may be either linear or branched. For the alkyl group included in the alkoxycarbonyl group, the number of carbon atoms is not particularly limited, but is preferably 1 to 5, and more preferably 1 to 3.

In the formula (S1), La₁ represents a single bond or a divalent linking group. Examples of the divalent linking group include a carbonyl group (—CO—), —O—, —S—, —SO—, —SO₂—, amide groups (—CONR—), sulfonamide groups (—SO₂NR—), alkylene groups, cycloalkylene groups, alkenylene groups, and linking groups in which a plurality of the foregoing are linked together. The above-described R's each represent a hydrogen atom or an organic group, and the organic group is preferably an alkyl group, a cycloalkyl group, an aryl group, or a combination thereof.

La₁ is preferably a single bond or —COO—, and more preferably a single bond.

In the formula (S1), Ra₄ to Ra₆ each independently represent a hydrogen atom, an alkyl group, a cycloalkyl group, an aryl group, an aromatic heterocyclic group, an aralkyl group, or an alkenyl group.

For Ra₄ to Ra₆, the alkyl group may be either linear or branched. The number of carbon atoms of the alkyl group is not particularly limited, but is preferably 1 to 10, and more preferably 1 to 6. For Ra₄ to Ra₆, the methylene group included in the alkyl group may be replaced by at least one of —CO— or —O—.

For Ra₄ to Ra₆, the number of carbon atoms of the cycloalkyl group of is not particularly limited, but is preferably 3 to 20, and more preferably 5 to 15. For Ra₄ to Ra₆, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ra₄ to Ra₆, the number of carbon atoms of the aryl group is not particularly limited, but is preferably 6 to 20, and more preferably 6 to 10. For Ra₄ to Ra₆, the aryl group is most preferably a phenyl group.

For Ra₄ to Ra₆, the aralkyl group is preferably a group in which one hydrogen atom in the above-described alkyl group for Ra₄ to Ra₆ is substituted with an aryl group having 6 to 10 carbon atoms (preferably a phenyl group), and examples thereof include a benzyl group.

For Ra₄ to Ra₆, the number of carbon atoms of the alkenyl group is not particularly limited, but is preferably 2 to 5, and more preferably 2 to 4. For Ra₄ to Ra₆, the alkenyl group is preferably a vinyl group.

For Ra₄ to Ra₆, the aromatic heterocyclic group preferably includes at least one heteroatom selected from the group consisting of a sulfur atom, a nitrogen atom, and an oxygen atom. The number of heteroatoms included in the aromatic heterocyclic group is preferably 1 to 5, and more preferably 1 to 3. The number of carbon atoms of the aromatic heterocyclic group is not particularly limited, but is preferably 2 to 20, and more preferably 3 to 15. The aromatic heterocyclic group may be monocyclic or polycyclic. For Ra₄ to Ra₆, examples of the aromatic heterocyclic group include a thienyl group, a furanyl group, a benzothienyl group, a dibenzothienyl group, a benzofuranyl group, a pyrrole group, an oxazolyl group, a thiazolyl group, a pyridyl group, an isothiazolyl group, and a thiadiazolyl group.

Two of Ra₄ to Ra₆ may be bonded together to form a ring. The group formed by bonding together two of Ra₄ to Ra₆ to form a ring is preferably a cycloalkyl group. The cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms. In the cycloalkyl group, one of the methylene groups constituting the ring may be replaced with a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

In the formula (S1), —C(Ra₄)(Ra₅)(Ra₆) is preferably a leaving group and —COO—C(Ra₄)(Ra₅)(Ra₆) is preferably subjected to the action of an acid to undergo leaving of C(Ra₄)(Ra₅)(Ra₆) to generate a carboxyl group.

In the formula (S1), Ra₀ represents a substituent. Ra₀ preferably represents an alkyl group, a cycloalkyl group, an aryl group, an aromatic heterocyclic group, an alkoxy group, an acyloxy group, an alkoxycarbonyl group, a halogen atom, a hydroxy group, a carboxy group, or a cyano group.

For Ra₀, the alkyl group may be either linear or branched. The number of carbon atoms of the alkyl group is not particularly limited, but is preferably 1 to 5, and more preferably 1 to 3.

For Ra₀, the number of carbon atoms of the cycloalkyl group is not particularly limited, but is preferably 3 to 20, and more preferably 5 to 15. For Ra₀, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ra₀, examples of the halogen atom include a fluorine atom, a chlorine atom, a bromine atom, and an iodine atom, and preferred is a fluorine atom or an iodine atom.

For Ra₀, the alkyl group included in the alkoxy group may be either linear or branched. For the alkyl group included in the alkoxy group, the number of carbon atoms is not particularly limited, but is preferably 1 to 5, and more preferably 1 to 3.

For Ra₀, the alkyl group that can be included in the acyloxy group may be either linear or branched. For the alkyl group that can be included in the acyloxy group for Ra₀, the number of carbon atoms is not particularly limited, but is preferably 1 to 5, and more preferably 1 to 3.

For the aryl group that can be included in the acyloxy group for Ra₀, the number of carbon atoms is not particularly limited, but is preferably 6 to 20, and more preferably 6 to 10. For Ra₀, the aryl group that can be included in the acyloxy group is most preferably a phenyl group.

For Ra₀, the alkyl group included in the alkoxycarbonyl group may be either linear or branched. For the alkyl group included in the alkoxycarbonyl group, the number of carbon atoms is not particularly limited, but is preferably 1 to 5, and more preferably 1 to 3.

For the aryl group for Ra₀, the number of carbon atoms is not particularly limited, but is preferably 6 to 20, and more preferably 6 to 10. The aryl group of Ra₀ is most preferably a phenyl group.

For Ra₀, the aralkyl group is preferably a group in which one hydrogen atom in the above-described alkyl group for Ra₀ is substituted with an aryl group having 6 to 10 carbon atoms (preferably a phenyl group), and examples thereof include a benzyl group.

For the alkenyl group for Ra₀, the number of carbon atoms is not particularly limited, but is preferably 2 to 5, and more preferably 2 to 4. For Ra₀, the alkenyl group is preferably a vinyl group.

For Ra₀, the aromatic heterocyclic group preferably includes at least one heteroatom selected from the group consisting of a sulfur atom, a nitrogen atom, and an oxygen atom. The number of heteroatoms included in the aromatic heterocyclic group is preferably 1 to 5, and more preferably 1 to 3. The number of carbon atoms of the aromatic heterocyclic group is not particularly limited, but is preferably 2 to 20, and more preferably 3 to 15. The aromatic heterocyclic group may be monocyclic or polycyclic. For Ra₀, examples of the aromatic heterocyclic group include a thienyl group, a furanyl group, a benzothienyl group, a dibenzothienyl group, a benzofuranyl group, a pyrrole group, an oxazolyl group, a thiazolyl group, a pyridyl group, an isothiazolyl group, and a thiadiazolyl group.

In the formula (S1), na represents an integer of 0 to 4, preferably represents an integer of 0 to 2, more preferably represents 0 or 1, and still more preferably represents 0.

In the formula (S1), ma represents an integer of 0 to 2, preferably represents 0 or 1, and more preferably represents 0. In the formula (S1), the aromatic ring is benzene when ma represents 0, is naphthalene when ma represents 1, or is anthracene when ma represents 2.

Non-limiting specific examples of the repeating unit represented by the formula (S1) are as follows.

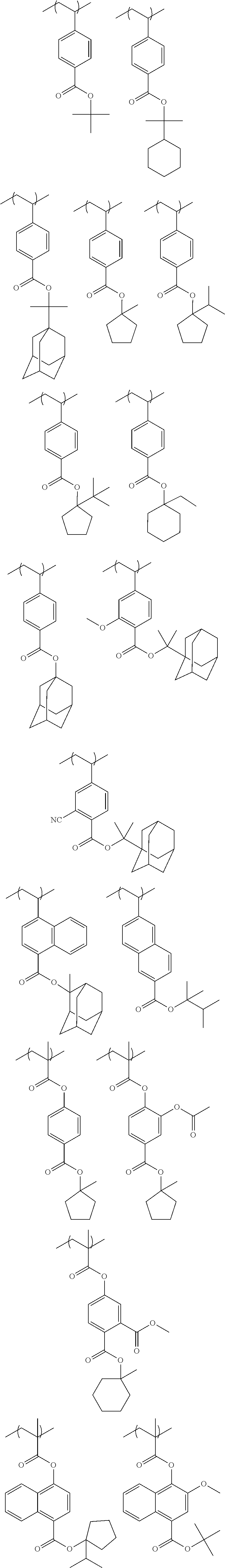

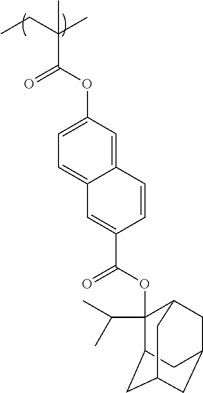

### Repeating Unit Represented by Formula (S2)

In the formula (S2), Ra₇ to Ra₉ each independently represent a hydrogen atom, an alkyl group, a cycloalkyl group, a halogen atom, a cyano group, or an alkoxycarbonyl group. The descriptions, specific examples, and preferred ranges of Ra₇ to Ra₉ are the same as the above descriptions, specific examples, and preferred ranges of Ra₁ to Ra₃ in the formula (S1).

In the formula (S2), La₂ represents a single bond or a divalent linking group. The descriptions, specific examples, and preferred ranges of La₂ are the same as the above descriptions, specific examples, and preferred ranges of La₁ in the formula (S1).

In the formula (S2), Ara represents an aromatic ring group. The aromatic ring group of Ara is preferably an arylene group, more preferably an arylene group having 6 to 20 carbon atoms, still more preferably an arylene group having 6 to 10 carbon atoms, particularly preferably a phenylene group or a naphthylene group, and most preferably a phenylene group.

In the formula (S2), Ra₁₀ to Ra₁₂ each independently represent a hydrogen atom, an alkyl group, a cycloalkyl group, an aryl group, an aromatic heterocyclic group, an aralkyl group, an alkoxy group, a cycloalkyloxy group, or an alkenyl group.

For Ra₁₀ to Ra₁₂, the alkyl group may be either linear or branched. The number of carbon atoms of the alkyl group is not particularly limited, but is preferably 1 to 5, and more preferably 1 to 3.

For Ra₁₀ to Ra₁₂, the number of carbon atoms of the cycloalkyl group is not particularly limited, but is preferably 3 to 20, and more preferably 5 to 15. For Ra₁₀ to Ra₁₂, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ra₁₀ to Ra₁₂, the alkyl group included in the alkoxy group may be either linear or branched. The number of carbon atoms of the alkyl group included in the alkoxy group is not particularly limited, but is preferably 1 to 5, and more preferably 1 to 3.

For Ra₁₀ to Ra₁₂, the number of carbon atoms of the cycloalkyl group included in the cycloalkyloxy group is not particularly limited, but is preferably 3 to 20, and more preferably 5 to 15. For Ra₁₀ to Ra₁₂, the cycloalkyl group included in the cycloalkyloxy group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ra₁₀ to Ra₁₂, the number of carbon atoms of the aryl group is not particularly limited, but is preferably 6 to 20, and more preferably 6 to 10. For Ra₁₀ to Ra₁₂, the aryl group is most preferably a phenyl group.

For Ra₁₀ to Ra₁₂, the aralkyl group is preferably a group in which one hydrogen atom in the above-described alkyl group for Ra₁₀ to Ra₁₂ is substituted with an aryl group having 6 to 10 carbon atoms (preferably a phenyl group), and examples thereof include a benzyl group.

For Ra₁₀ to Ra₁₂, the number of carbon atoms of the alkenyl group is not particularly limited, but is preferably 2 to 5, and more preferably 2 to 4. For Ra₁₀ to Ra₁₂, the alkenyl group is preferably a vinyl group.

For Ra₁₀ to Ra₁₂, the aromatic heterocyclic group preferably includes at least one heteroatom selected from the group consisting of a sulfur atom, a nitrogen atom, and an oxygen atom. The number of heteroatoms included in the aromatic heterocyclic group is preferably 1 to 5, and more preferably 1 to 3. The number of carbon atoms of the aromatic heterocyclic group is not particularly limited, but is preferably 2 to 20, and more preferably 3 to 15. The aromatic heterocyclic group may be monocyclic or polycyclic. For Ra₁₀ to Ra₁₂, examples of the aromatic heterocyclic group include a thienyl group, a furanyl group, a benzothienyl group, a dibenzothienyl group, a benzofuranyl group, a pyrrole group, an oxazolyl group, a thiazolyl group, a pyridyl group, an isothiazolyl group, and a thiadiazolyl group.

At least two of Ra₁₀ to Ra₁₂ may be bonded together to form a ring. The group formed by bonding together Ra₁₀ to Ra₁₂ to form a ring is preferably a cycloalkyl group. The cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms. In the cycloalkyl group, one of the methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

At least one of Ra₁₀ to Ra₁₂ is preferably an alkoxy group; more preferably, one of Ra₁₀ to Ra₁₂ is an alkoxy group and the other two are a hydrogen atom, an alkyl group, a cycloalkyl group, or an aryl group.

In the formula (S2), —C(Ra₁₀)(Ra₁₁)(Ra₁₂) is preferably a leaving group, and —O—C(Ra₁₀)(Ra₁₁)(Ra₁₂) is preferably subjected to the action of an acid to undergo leaving of —C(Ra₁₀)(Ra₁₁)(Ra₁₂) to generate a hydroxy group (this hydroxy group is bonded to Ara and hence is a phenolic hydroxy group).

Non-limiting specific examples of the repeating unit represented by the formula (S2) are as follows.

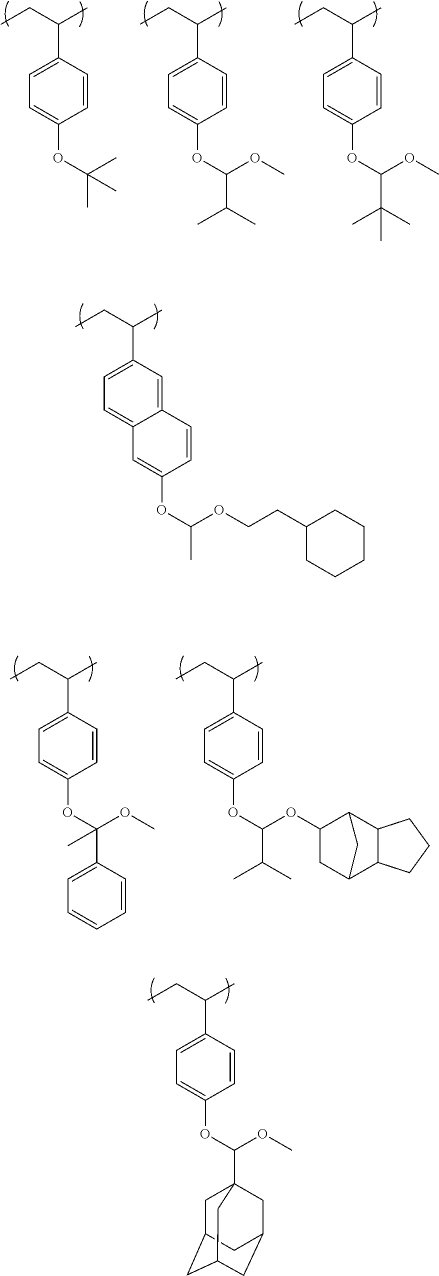

The content of the repeating unit having an acid-decomposable group in the resin (A) is not particularly limited, but is, relative to all the repeating units in the resin (A), preferably 5 mol % or more, more preferably 10 mol % or more, and still more preferably 15 mol % or more. The content of the repeating unit having an acid-decomposable group is, relative to all the repeating units in the resin (A), preferably 70 mol % or less, more preferably 60 mol % or less, and still more preferably 50 mol % or less.

The repeating unit having an acid-decomposable group included in the resin (A) may be of one type, or may be of two or more types. When the resin (A) includes two or more types of repeating units having an acid-decomposable group, the total content thereof is preferably within such a preferred content range.

### Repeating Unit Represented by Formula (S3)

The resin (A) preferably includes a repeating unit having a phenolic hydroxyl group. The repeating unit having a phenolic hydroxyl group is preferably a repeating unit represented by the following formula (S3).

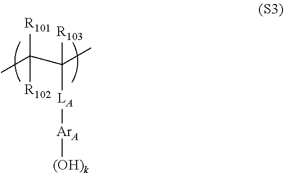

In the formula (S3), R₁₀₁, R₁₀₂, and R₁₀₃ each independently represent a hydrogen atom, an alkyl group, a cycloalkyl group, a halogen atom, a cyano group, or an alkoxycarbonyl group. R₁₀₂ may be bonded to Ar_{A} to form a ring and, in this case, R₁₀₂ represents a single bond or an alkylene group. L_{A} represents a single bond or a divalent linking group. Ar_{A} represents an aromatic ring group. k represents an integer of 1 to 5.

In the formula (S3), R₁₀₁, R₁₀₂, and R₁₀₃ each independently represent a hydrogen atom, an alkyl group, a cycloalkyl group, a halogen atom, a cyano group, or an alkoxycarbonyl group. The descriptions, specific examples, and preferred ranges of R₁₀₁, R₁₀₂, and R₁₀₃ are the same as the above descriptions, specific examples, and preferred ranges of Ra₁ to Ra₃ in the formula (S1).

In the formula (S3), Ar_{A} represents an aromatic ring group, and more specifically, represents a (k+1) valent aromatic ring group. In a case where k is 1, the divalent aromatic ring group is, for example, preferably an arylene group having 6 to 18 carbon atoms such as a phenylene group, a tolylene group, a naphthylene group, or an anthracenylene group, or a divalent aromatic ring group including a heterocycle such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. The aromatic ring group may have a substituent.

In a case where k is an integer of 2 or more, specific examples of the (k+1) valent aromatic ring group include groups provided by removing any (k−1) hydrogen atoms from the above-described specific examples of the divalent aromatic ring group.

The (k+1) valent aromatic ring group may further have a substituent.

The substituent that the (k+1) valent aromatic ring group can have is not particularly limited, but examples thereof include alkyl groups such as a methyl group, an ethyl group, a propyl group, an isopropyl group, an n-butyl group, a sec-butyl group, a hexyl group, a 2-ethylhexyl group, an octyl group, and a dodecyl group; alkoxy groups such as a methoxy group, an ethoxy group, a hydroxyethoxy group, a propoxy group, a hydroxypropoxy group, and a butoxy group; aryl groups such as a phenyl group; and the like.

Ar_{A} preferably represents an aromatic ring group having 6 to 18 carbon atoms, and more preferably represents a benzene ring group, a naphthalene ring group, or a biphenylene ring group.

In the formula (S3), L_{A} represents a single bond or a divalent linking group.

The divalent linking group represented by L_{A} is not particularly limited, but examples thereof include —COO—, —CONR₁₀₄—, alkylene groups, and groups in which two or more of such groups are combined together. R₁₀₄ above represents a hydrogen atom or an alkyl group.

The alkylene group is not particularly limited, but is preferably an alkylene group having 1 to 8 carbon atoms such as a methylene group, an ethylene group, a propylene group, a butylene group, a hexylene group, and an octylene group.

When R₁₀₄ represents an alkyl group, examples of the alkyl group include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

The repeating unit represented by the formula (S3) preferably includes a hydroxystyrene structure. In other words, Ar_{A} preferably represents a benzene ring group.

k preferably represents an integer of 1 to 3, more preferably represents 1 or 2, and still more preferably represents 1.

Particularly preferably, Ar_{A} is a benzene ring group, k is 1, and OH is at the para position of L_{A}.

The content of the repeating unit having a phenolic hydroxyl group in the resin (A) is not particularly limited, but is, relative to all the repeating units in the resin (A), preferably 20 mol % or more, more preferably 30 mol % or more, and still more preferably 40 mol % or more. The content of the repeating unit having a phenolic hydroxyl group is, relative to all the repeating units in the resin (A), preferably 90 mol % or less, more preferably 85 mol % or less, and still more preferably 80 mol % or less.

The repeating unit having a phenolic hydroxyl group included in the resin (A) may be of one type, or may be of two or more types. When the resin (A) includes two or more types of repeating units having a phenolic hydroxyl group, the total content thereof is preferably within such a preferred content range.

The resin (A) may include, in addition to the repeating unit having an acid-decomposable group and the repeating unit having a phenolic hydroxyl group, another repeating unit.

### Repeating Unit Having Photoacid Generation Group

The resin (A) may have, as a repeating unit other than the above-described repeating units, a repeating unit having a group that generates an acid upon irradiation with an actinic ray or a radiation (preferably an electron beam or extreme ultraviolet rays) (hereafter, also referred to as a “photoacid generation group”).

Examples of the repeating unit having a photoacid generation group include a repeating unit represented by the following formula (S4).

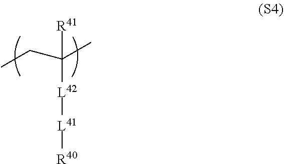

In the formula (S4), R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

L⁴¹ represents a single bond or a divalent linking group, and preferably represents a single bond or an ester bond (—COO—).

L⁴² is preferably a linking group formed of at least one selected from the group consisting of an alkylene group, a cycloalkylene group, an arylene group, —O—, —CO—, —S—, —SO—, —SO₂—, and —NR—. R represents a hydrogen atom or an organic group (preferably an organic group having 1 to 10 carbon atoms, such as an alkyl group, a cycloalkyl group, or an aryl group).

The alkylene group may be either linear or branched. The number of carbon atoms of the alkylene group is not particularly limited, but is preferably 1 to 10.

The cycloalkylene group may be a monocyclic cycloalkylene group or a polycyclic cycloalkylene group. The number of carbon atoms of the cycloalkylene group is not particularly limited, but is preferably 3 to 20, and more preferably 5 to 15.

The number of carbon atoms of the arylene group is not particularly limited, but is preferably 6 to 20, and more preferably 6 to 10.

The alkylene group, the cycloalkylene group, and the arylene group may have a substituent, and examples of the substituent include the above-described Substituents T.

R⁴⁰ is preferably a group represented by the following formula (S4-1).

*-Q⁻M⁺ (S4-1)

In the formula (S4-1), Q⁻ represents an acid residue and M⁺ represents a cation. * represents a bonding site to L⁴¹.

The acid residue is a group formed by dissociation of a proton from an acid.

Q⁻ is preferably a carboxylate anion group (COO⁻), a sulfonate anion group (SO₃⁻), or a sulfonamide group (represented by N⁻—SO₂R^{N1} where R^{N1} represents an organic group; examples thereof include organic groups having 1 to 10 carbon atoms, and preferred are alkyl groups, fluoroalkyl groups, and aryl groups), and more preferably a sulfonate anion group.

The descriptions, specific examples, and preferred ranges of M⁺ are the same as those described later for M⁺ in the acid generator (C).

Examples of the repeating unit having a photoacid generation group include the repeating units described in Paragraphs [0094] to [0105] of JP2014-041327A, and the repeating units described in Paragraph [0094] of WO2018/193954A.

When the resin (A) includes a repeating unit having a photoacid generation group, the content of the repeating unit having a photoacid generation group is, relative to all the repeating units in the resin (A), preferably 1 mol % or more, and more preferably 5 mol % or more. The content of the repeating unit having a photoacid generation group is, relative to all the repeating units in the resin (A), preferably 40 mol % or less, more preferably 35 mol % or less, and still more preferably 30 mol % or less.

When the resin (A) includes a repeating unit having a photoacid generation group, the repeating unit having a photoacid generation group may be of one type, or may be of two or more types. When the resin (A) includes two or more types of repeating units having a photoacid generation group, the total content thereof is preferably within such a preferred content range.

### Repeating Unit Represented by Formula (V-1) or Formula (V-2) Below

The resin (A) may include a repeating unit represented by the following formula (V-1) or the following formula (V-2).

The repeating unit represented by the following formula (V-1) and the repeating unit represented by the following formula (V-2) are preferably repeating units different from the above-described repeating unit having an acid-decomposable group and the above-described repeating unit having a phenolic hydroxyl group.

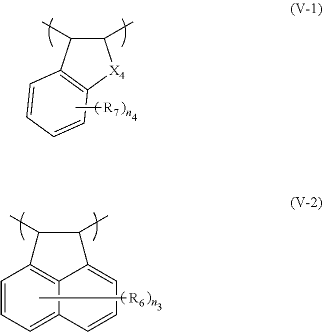

In the formula, R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR where R is an alkyl group or a fluorinated alkyl group having 1 to 6 carbon atoms), or a carboxy group. The alkyl group is preferably a linear, branched, or cyclic alkyl group having 1 to 10 carbon atoms. n₃ represents an integer of 0 to 6. n₄ represents an integer of 0 to 4. X₄ is a methylene group, an oxygen atom, or a sulfur atom.

Examples of the repeating unit represented by the formula (V-1) or (V-2) include the repeating units described in Paragraph [0100] of WO2018/193954A.

When the resin (A) includes the repeating unit represented by the formula (V-1) or (V-2), the content of the repeating unit represented by the formula (V-1) or (V-2) is, relative to all the repeating units in the resin (A), preferably 1 mol % or more, and more preferably 5 mol % or more. The content of the repeating unit represented by the formula (V-1) or (V-2) is, relative to all the repeating units in the resin (A), preferably 40 mol % or less, more preferably 35 mol % or less, and still more preferably 30 mol % or less.

When the resin (A) includes a repeating unit represented by the formula (V-1) or (V-2), the repeating unit represented by the formula (V-1) or (V-2) may be of one type, or may be of two or more types. When the resin (A) includes two or more types of repeating units represented by the formula (V-1) or (V-2), the total content thereof is preferably within such a preferred content range.

The resin (A) may include, in addition to the above-described repeating units, another repeating unit.

For the other repeating unit, the contents of [0112] to [0134] and [0144] to [0172] of WO2022/024928A are referred to.

The resin (A) can be synthesized in accordance with standard procedures (for example, radical polymerization).

The weight-average molecular weight (Mw) of the resin (A) as a polystyrene-equivalent value determined by the GPC method is preferably 30000 or less, more preferably 1000 to 30000, still more preferably 3000 to 30000, and particularly preferably 5000 to 15000.

The resin (A) has a dispersity (molecular weight distribution, Mw/Mn) of preferably 1 to 5, more preferably 1 to 3, still more preferably 1.2 to 3.0, and particularly preferably 1.2 to 2.0. As the dispersity lowers, the resolution becomes higher, the resist profile becomes better, the sidewalls of the resist pattern become smoother, and the roughness performance also becomes higher.

The content of the resin (A) in the composition of the present invention is, relative to the total solid content of the composition of the present invention, preferably 40.0 to 99.9 mass %, and more preferably 60.0 to 90.0 mass %.

Such resins (A) may be used alone or may be used in combination of two or more thereof. When two or more resins (A) are used, the total content thereof is preferably within such a preferred content range.

### Resin (B)

The resin (B) included in the composition of the present invention will be described.

The resin (B) is a resin not including an acid-decomposable group. The acid-decomposable group is as described above.

The resin (B) does not include an ammonium salt structure. The ammonium salt structure is a structure including an ammonium cation and an anion, and is typically a group represented by a formula (Am1) below. The resin (B) does not include a group represented by the following formula (Am1).

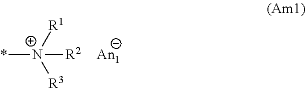

In the formula (Am1), R¹ to R³ each independently represent a hydrogen atom or an organic group. An₁ represents an anion. * represents a bonding site.

The resin (B) includes a repeating unit (b1) having a hydrophilic group and a fluorine atom. In the repeating unit (b1), the hydrophilic group and the fluorine atom are covalently bonded to the main chain of the resin (B), or are covalently bonded to a side chain covalently bonded to the main chain of the resin (B). The term “main chain” refers to the relatively longest bonding chain in the resin molecule, and the term “side chain” refers to the other bonding chains.

The hydrophilic group is preferably a group having a dissociative proton.

The hydrophilic group may be, for example, a hydroxy group, a carboxy group, a sulfonic acid group, a sulfonimide group, a phosphoric acid group, an aromatic thiol group, a nitric acid ester group, a sulfonamide group, an alkylsulfonylmethylene group, an alkylcarbonylmethylene group, an alkylsulfonylimide group, an alkylcarbonylimide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, or a polyoxyethylene group, is preferably a hydroxy group, a carboxy group, a sulfonic acid group, a sulfonimide group, a phosphoric acid group, an aromatic thiol group, a nitric acid ester group, or a sulfonamide group, more preferably a hydroxy group, a carboxy group, a sulfonic acid group, a sulfonimide group, or a phosphoric acid group, and still more preferably a hydroxy group or a carboxy group. The hydroxy group is particularly preferably a phenolic hydroxy group (a hydroxy group bonded to an aromatic ring).

The repeating unit (b1) of the resin (B) is preferably a repeating unit represented by the following formula (T1).

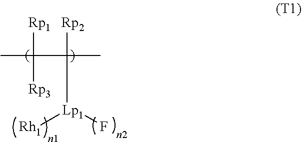

In the formula (T1), Rp₁ to Rp₃ each independently represent a hydrogen atom, an alkyl group, a cycloalkyl group, a halogen atom, a cyano group, or an alkoxycarbonyl group. Lp₁ represents a linking group. Rh₁ represents a hydrophilic group. n1 and n2 each independently represent an integer of 1 or more. When a plurality of Rh₁ are present, the plurality of Rh₁ may be the same or different. Two of Rp₁ to Rp₃ and Lp₁ may be bonded together to form a ring.

In the formula (T1), the descriptions, specific examples, and preferred ranges of Rp₁ to Rp₃ are the same as those described above for Ra₁ to Ra₃ in the formula (S1).

In the formula (T1), the linking group represented by Lp₁ is not particularly limited, but is preferably a linking group formed of at least one selected from the group consisting of an alkylene group, a cycloalkylene group, an arylene group, —O—, —CO—, —S—, —SO—, —SO₂—, and —NR—. R represents a hydrogen atom or an organic group (preferably an organic group having 1 to 10 carbon atoms, such as an alkyl group, a cycloalkyl group, or an aryl group).

The alkylene group may be either linear or branched. The number of carbon atoms of the alkylene group is not particularly limited, but is preferably 1 to 10, and more preferably 1 to 5.

The cycloalkylene group may be a monocyclic cycloalkylene group or a polycyclic cycloalkylene group. For the cycloalkylene group, the number of carbon atoms is not particularly limited, but is preferably 3 to 20, and more preferably 5 to 15.

For the arylene group, the number of carbon atoms is not particularly limited, but is preferably 6 to 20, and more preferably 6 to 10. The arylene group is preferably a phenylene group or a naphthylene group, and more preferably a phenylene group.

The alkylene group, the cycloalkylene group, and the arylene group may further have a substituent other than a hydrophilic group and a fluorine atom.

For the hydrophilic group represented by Rh₁ in the formula (T1), specific examples and preferred ranges are the same as those described above.

In the formula (T1), n1 represents an integer of 1 or more, preferably an integer of 1 to 5, and more preferably an integer of 1 to 3.

In the formula (T1), n2 represents an integer of 1 or more, is preferably an integer of 1 to 30, and more preferably an integer of 3 to 20.

The repeating unit represented by the formula (T1) is preferably a repeating unit represented by any of the following formulas (T2) to (T4).

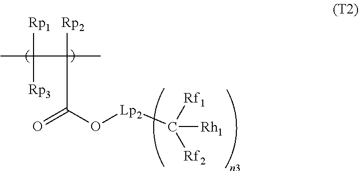

In the formula (T2), Rp₁ to Rp₃ and Rh₁ respectively have the same meanings as the above-described Rp₁ to Rp₃ and Rh₁ in the formula (T1). Lp₂ represents a linking group formed of at least one selected from the group consisting of an alkylene group, a cycloalkylene group, and an arylene group. Rf₁ and Rf₂ each independently represent a fluorine atom or a fluorinated alkyl group. n3 represents an integer of 1 or more. When a plurality of Rh₁, Rf₁, and Rf₂ are present, the plurality of Rh₁, Rf₁, and Rf₂ may be individually the same or different. Two of Rp₁ to Rp₃ may be bonded together to form a ring.

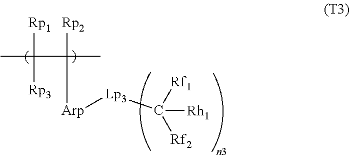

In the formula (T3), Rp₁ to Rp₃ and Rh₁ respectively have the same meanings as the above-described Rp₁ to Rp₃ and Rh₁ in the formula (T1). Arp represents an arylene group. Lp₃ represents a linking group formed of at least one selected from the group consisting of an alkylene group, a cycloalkylene group, —O—, and —CO—, or a single bond. Rf₁ and Rf₂ each independently represent a fluorine atom or a fluorinated alkyl group. n3 represents an integer of 1 or more. When a plurality of Rh₁, Rf₁, and Rf₂ are present, the plurality of Rh₁, Rf₁, and Rf₂ may be individually the same or different. Two of Rp₁ to Rp₃, Arp, and Lp₃ may be bonded together to form a ring.

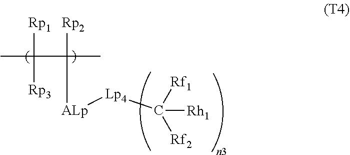

In the formula (T4), Rp₁ to Rp₃ and Rh₁ respectively have the same meanings as the above-described Rp₁ to Rp₃ and Rh₁ in the formula (T1). ALp represents a linking group formed of at least one selected from the group consisting of an alkylene group and a cycloalkylene group. Lp₄ represents a linking group formed of at least one selected from the group consisting of an arylene group, —O—, and —CO—, or a single bond. Rf₁ and Rf₂ each independently represent a fluorine atom or a fluorinated alkyl group. n3 represents an integer of 1 or more. When a plurality of Rh₁, Rf₁, and Rf₂ are present, the plurality of Rh₁, Rf₁, and Rf₂ may be individually the same or different. Two of Rp₁ to Rp₃, ALp, and Lp₄ may be bonded together to form a ring.

In the formulas (T2) to (T4), the descriptions, specific examples, and preferred ranges of Rp₁ to Rp₃ and Rh₁ are respectively the same as those described above for Rp₁ to Rp₃ and Rh₁ in the formula (T1).

In the formulas (T2) to (T4), Rf₁ and Rf₂ each independently represent a fluorine atom or a fluorinated alkyl group. The fluorinated alkyl group may be either linear or branched. The number of carbon atoms of the fluorinated alkyl group is not particularly limited, but is preferably 1 to 10, and more preferably 1 to 5. The fluorinated alkyl group is preferably a perfluoroalkyl group such as a trifluoromethyl group.

In the formulas (T2) to (T4), n3 represents an integer of 1 or more, and is preferably an integer of 1 to 10, more preferably an integer of 1 to 5, and still more preferably an integer of 1 to 3.

In the formula (T2), the descriptions, specific examples, and preferred ranges of the alkylene group, the cycloalkylene group, and the arylene group of Lp₂ are respectively the same as those described above in the cases where Lp₁ in the formula (T1) is an alkylene group, a cycloalkylene group, and an arylene group.

In the formula (T3), the descriptions, specific examples, and preferred ranges of the arylene group represented by Arp are the same as those described above in the case where Lp₁ in the formula (T1) is an arylene group.

In the formula (T3), the descriptions, specific examples, and preferred ranges of the alkylene group and the cycloalkylene group of Lp₃ are respectively the same as those described above in the cases where Lp₁ in the formula (T1) is an alkylene group and a cycloalkylene group.

In the formula (T4), the descriptions, specific examples, and preferred ranges of the alkylene group and the cycloalkylene group represented by ALp are respectively the same as those described above in the cases where Lp₁ in the formula (T1) is an alkylene group and a cycloalkylene group.

In the formula (T4), the descriptions, specific examples, and preferred ranges of the arylene group represented by Lp₄ are the same as those described above in the case where Lp₁ in the formula (T1) is an arylene group.

The content of the repeating unit (b1) in the resin (B) is not particularly limited, but is, relative to all the repeating units in the resin (B), preferably 10 mol % or more, more preferably 20 mol % or more, and still more preferably 30 mol % or more. The content of the repeating unit (b1) is, relative to all the repeating units in the resin (B), preferably 90 mol % or less, more preferably 85 mol % or less, and still more preferably 80 mol % or less.

The repeating unit (b1) included in the resin (B) may be of one type, or may be of two or more types. When the resin (B) includes two or more types of the repeating unit (b1), the total content thereof is preferably within such a preferred content range.

The resin (B) may include, in addition to the repeating unit (b1), a repeating unit other than the repeating unit (b1).

The repeating unit other than the repeating unit (b1) is preferably a repeating unit having any one or more of a fluorine atom, a silicon atom, and a hydrocarbon group having 5 or more carbon atoms. The hydrocarbon group having 5 or more carbon atoms is preferably an alkyl group or a cycloalkyl group, and more preferably a branched alkyl group or a cycloalkyl group.

The repeating unit other than the repeating unit (b1) is preferably a repeating unit represented by the following formula (T5).

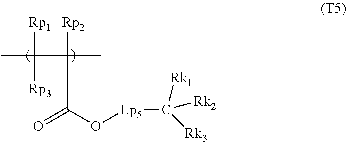

In the formula (T5), Rp₁ to Rp₃ respectively have the same meanings as the above-described Rp₁ to Rp₃ in the formula (T1). Lp₅ represents a single bond or a divalent linking group. Rk₁ to Rk₃ each independently represent a hydrogen atom, a fluorine atom, an alkyl group, a cycloalkyl group, an alkenyl group, an aryl group, or a group including a silicon atom. At least two of Rk₁ to Rk₃ may be bonded together to form a ring.

The descriptions, specific examples, and preferred ranges of Rp₁ to Rp₃ are respectively the same as those described above for Rp₁ to Rp₃ in the formula (T1).

Lp₅ represents a single bond or a divalent linking group. Examples of the divalent linking group include a carbonyl group (—CO—), —O—, —S—, —SO—, —SO₂—, amino groups (—NR—), amide groups (—CONR—), sulfonamide groups (—SO₂NR—), alkylene groups, cycloalkylene groups, alkenylene groups, arylene groups, and linking groups in which a plurality of the foregoing are linked together. The above-described R's each represent a hydrogen atom or an organic group, and the organic group is preferably an alkyl group, a cycloalkyl group, an aryl group, or a combination of the foregoing.

Lp₅ is preferably a single bond.

When Rk₁ to Rk₃ represent an alkyl group, preferred is an alkyl group having 1 to 20 carbon atoms, and more preferred is an alkyl group having 1 to 10 carbon atoms. The alkyl group may have a substituent, and the substituent is preferably a fluorine atom. The alkyl group may be linear or branched, but when the alkyl group does not have a substituent, preferred is an alkyl group having 3 or more carbon atoms, and more preferred is a branched alkyl group having 3 or more carbon atoms. When the alkyl group is a fluorinated alkyl group, it is preferably a fluorinated alkyl group having 1 to 8 carbon atoms.

When Rk₁ to Rk₃ represent a cycloalkyl group, the number of carbon atoms of the cycloalkyl group is not particularly limited, but is preferably 3 to 20, and more preferably 5 to 15. The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group.

When Rk₁ to Rk₃ represent an alkenyl group, preferred is an alkenyl group having 2 to 20 carbon atoms, and more preferred is an alkenyl group having 2 to 10 carbon atoms.

When Rk₁ to Rk₃ represent an aryl group, preferred is an aryl group having 6 to 20 carbon atoms, and more preferred is an aryl group having 6 to 10 carbon atoms.

At least two of Rk₁ to Rk₃ may be bonded together to form a ring. Examples of the formed ring include cycloalkane structures (for example, an adamantane structure) and lactone structures.

However, the resin (B) does not include an acid-decomposable group and hence Rk₁ to Rk₃ do not simultaneously represent alkyl groups, cycloalkyl groups, alkenyl groups, or aryl groups. When two of Rk₁ to Rk₃ are bonded together to form a ring, the remaining one does not represent an alkyl group, a cycloalkyl group, an alkenyl group, or an aryl group.

When the resin (B) includes a repeating unit other than the repeating unit (b1), the content of the repeating unit other than the repeating unit (b1) relative to all the repeating units in the resin (B) is preferably 1 mol % or more, and more preferably 5 mol % or more. The content of the repeating unit other than the repeating unit (b1) relative to all the repeating units in the resin (B) is preferably 40 mol % or less, more preferably 35 mol % or less, still more preferably 30 mol % or less.

When the resin (B) includes a repeating unit other than the repeating unit (b1), the repeating unit other than the repeating unit (b1) may be of one type, or may be of two or more types. When the resin (B) includes two or more types of repeating units other than the repeating unit (b1), the total content thereof is preferably within such a preferred content range.

The resin (B) preferably does not have an alkali-decomposable group.

The alkali-decomposable group is a group that is decomposed by the action of an alkali developer to cause an increase in the degree of solubility in the alkali developer. The alkali-decomposable group is typically a group represented by X in the partial structure represented by the following formula (KA-1) or (KB-1).

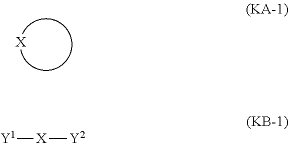

In the formula (KA-1) or (KB-1), X represents a carboxylic acid ester group: —COO—, an acid anhydride group: —C(O)OC(O)—, an acid imide group: —NHCONH—, a carboxylic acid thioester group: —COS—, a carbonic acid ester group: —OC(O)O—, a sulfuric acid ester group: —OSO₂O—, or a sulfonic acid ester group: —SO₂O—.

Y¹ and Y² each independently represent an electron-withdrawing group.

The partial structure represented by the formula (KA-1) is a structure that forms, together with the group serving as X, a ring structure.

Examples of the partial structure represented by the formula (KA-1) include a lactone ring structure. Specific examples of the lactone ring structure are as follows.

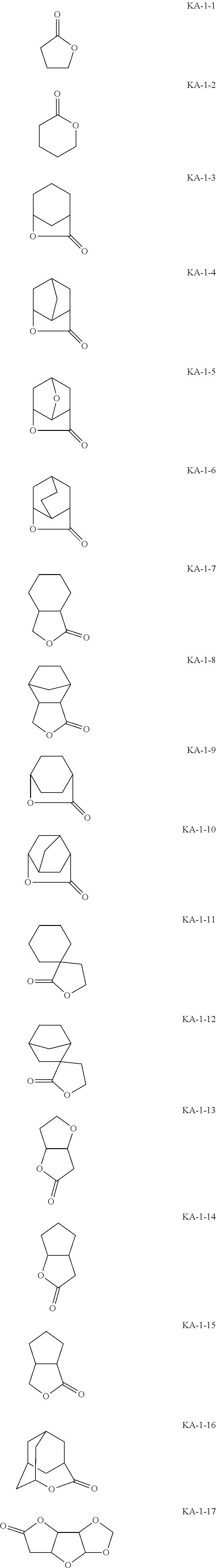

In the formula (KB-1), Y¹ and Y² each independently represent an electron-withdrawing group.

Examples of the electron-withdrawing group include groups represented by the following formula (EW). In the formula (EW), * represents a bonding site to X.

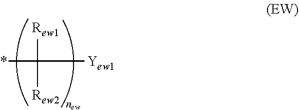

In the formula (EW), n_{ew} is the repeat number of a linking group represented by —C(R_{ew1})(R_{ew2})—, and represents 0 or 1. When n_{ew} is 0, it represents a single bond, and indicates that Y_{ew1} is directly bonded. Y_{ew1} represents a halogen atom, a cyano group, a nitrile group, a nitro group, a halo(cyclo)alkyl group or a haloaryl group represented by —C(R_{f1})(R_{f2})—R_{f3}, an oxy group, a carbonyl group, a sulfonyl group, a sulfinyl group, or a combination of the foregoing. The “halo(cyclo)alkyl group” represents an alkyl group and a cycloalkyl group that are at least partially halogenated, and the “haloaryl group” represents an aryl group that is at least partially halogenated. R_{f1} represents a halogen atom, a perhaloalkyl group, a perhalocycloalkyl group, or a perhaloaryl group. R_{f2} and R_{f3} each independently represent a hydrogen atom, a halogen atom, or an organic group, and R_{f2} and R_{f3} may be linked together to form a ring. R_{ew1} and R_{ew2} each independently represent a hydrogen atom or an appropriate substituent, and represent, for example, a hydrogen atom, an alkyl group, a cycloalkyl group, or an aryl group. At least two of R_{ew1}, R_{ew2}, and Y_{ew1} may be linked together to form a ring.

The sum (also referred to as “P_{B}”) of values obtained by multiplying the C log P of each repeating unit included in the resin (B) by the molar fraction of the repeating unit is preferably 0 or less.

When the resin (B) includes n types of repeating units, P_{B} is determined by the following formula (1). n represents an integer of 1 or more.

$${P}_{B} = {\sum }_{i = 1}^{n} ( {p}_{i} \cdot \frac{{m}_{i}}{100} ) \qquad Formula ( 1 )$$

In the formula (1), pᵢ represents the C log P of each repeating unit included in the resin (B), and mᵢ represents the molar fraction of each repeating unit (a mole-based ratio of each repeating unit relative to all the repeating units in the resin (B), and the unit is mol %).

The C log P is a value determined by calculating a common logarithm log P of a partition coefficient P between 1-octanol and water. The method and software used for the calculation of the C log P can be publicly known methods and software; however, unless otherwise specified, in the present invention, the C log P program incorporated in the ChemBioDraw Ultra 12.0 manufactured by Cambridge Soft Corporation is used.

The C log P of each repeating unit is the C log P of a monomer corresponding to the repeating unit, and the C log P of a monomer having a dissociative proton is calculated for a structure in which the proton is dissociated.

When P_{B} is 0 or less, the resin (B) is easily dissolved, generation of residue is suppressed, and a pattern having a square profile is easily formed, which is preferred. P_{B} is more preferably −1 or less, and still more preferably −2 or less.

The distances Ra between the Hansen solubility parameters of the resin (B) and the Hansen solubility parameters of air is preferably 35 MPa^{0.5} or less.

The Hansen solubility parameters (Hansen solubility parameter; HSP) are composed of three components: a dispersion force term δd, a dipolar intermolecular force term δp, and a hydrogen bonding force term δh.

The Hansen solubility parameters (HSP₁) (that is, the values of δd₁, δp₁, and δh₁) of the resin (B) are calculated by the Y-MB method using HSPiP (4th edition, 4.1.07), which is software capable of calculating HSP values from chemical structural formulas of compounds.

In addition, the Hansen solubility parameters (HSP₂) of air (that is, the values of δd₂, δp₂, and δh₂) are calculated by taking the weighted average of the HSPs of nitrogen and oxygen described in the HSPiP manual (ver. 4, e-Book Chapter19).

The distance Ra between HSP₁ and HSP₂ is calculated by the following formula (2).

$$Ra = {\{ 4 {( δ {d}_{1} - δ {d}_{2} )}^{2} + {( δ {p}_{1} - δ {p}_{2} )}^{2} + {( δ {h}_{1} \to δ {h}_{2} )}^{2} \}}^{0.5} \qquad Formula ( 2 )$$

δd₁ represents the dispersion force term δd of the resin (B); δd₂ represents the dispersion force term δd of air; δp₁ represents the dipolar intermolecular force term δp of the resin (B); δp₂ represents the dipolar intermolecular force term δp of air; δh₁ represents the hydrogen bonding force term δh of the resin (B); and δh₂ represents the hydrogen bonding force term δh of air.

δd₁, δp₁, and δh₁ are individually the sum of values obtained by multiplying the dispersion force term δd, the dipolar intermolecular force term δp, and the hydrogen bonding force term δh of each repeating unit included in the resin (B), by the molar fraction of the repeating unit. δd, δp, and δh of each repeating unit are δd, δp, and δh of a monomer corresponding to the repeating unit; and in the case of a monomer having a dissociative proton, δd, δp, and δh are calculated for a structure in which the proton is not dissociated.

When Ra is 35 MPa^{0.5} or less, the affinity for the resin (A) is lowered, so that the resolution is further improved. Ra is more preferably 33 MPa^{0.5} or less, and still more preferably 30 MPa^{0.5} or less.

The sum (also referred to as “F_{B}”) of values obtained by multiplying the value obtained by dividing the number of fluorine atoms in each repeating unit included in the resin (B) by the number of all atoms, by the molar fraction of the repeating unit is preferably 10 mol % or more.

F_{B} is calculated for a monomer corresponding to each repeating unit. In the case of a monomer having a dissociative proton, F_{B} is calculated for a structure in which the proton is not dissociated.

When the resin (B) includes n types of repeating units, F_{B} is determined by the following formula (3). n represents an integer of 1 or more.

$${F}_{B} = {\sum }_{i = 1}^{n} ( {f}_{i} \cdot \frac{{m}_{i}}{100} ) \qquad Formula ( 3 )$$

In the formula (3), fᵢ represents a value obtained by dividing the number of fluorine atoms in each repeating unit included in the resin (B) by the number of all atoms, and mᵢ represents the molar fraction of each repeating unit (a mole-based ratio of each repeating unit relative to all repeating units in the resin (B), and the unit is mol %).

When F_{B} is 10 mol % or more, the resin (B) is easily dissolved, generation of residue is suppressed, and a pattern having a square profile is easily formed, which is preferred. In addition, the affinity for the resin (A) is lowered, so that the resolution is further improved, which is preferred. F_{B} is more preferably 15 mol % or more, and still more preferably 25 mol % or more.

The above-described P_{B}, Ra, and F_{B} can be adjusted, for example, by changing the types of the repeating unit (b1) and the repeating unit other than the repeating unit (b1), and the contents thereof.

The resin (B) can be synthesized in accordance with standard procedures (for example, radical polymerization).

The weight-average molecular weight (Mw) of the resin (B) as a polystyrene-equivalent value determined by the GPC method is preferably 30000 or less, more preferably 1000 to 30000, still more preferably 3000 to 30000, and particularly preferably 5000 to 15000.

The dispersity (molecular weight distribution, Mw/Mn) of the resin (B) is preferably 1 to 5, more preferably 1 to 3, still more preferably 1.2 to 3.0, and particularly preferably 1.2 to 2.0.

The content of the resin (B) relative to the total solid content of the composition of the present invention is preferably 0.01 to 30.0 mass %, and more preferably 0.1 to 20.0 mass %.

Such resins (B) may be used alone or may be used in combination of two or more thereof. When two or more resins (B) are used, the total content thereof is preferably within such a preferred content range.

### Acid Generator (C)

The acid generator (C) included in the composition of the present invention will be described.

The acid generator (C) is preferably a compound (photoacid generator) that generates an acid upon irradiation with an actinic ray or a radiation.

The acid generated from the acid generator (C) (generated acid) has a pKa of 1.0 or less, preferably −5.0 or more and 1.0 or less, and more preferably −3.0 or more and 1.0 or less.

The acid generator (C) may have the form of a low molecular weight compound, or may have the form of being incorporated into a portion of a polymer (for example, the resin (A)). The form of a low molecular weight compound and the form of being incorporated into a portion of a polymer (for example, the resin (A)) may be used in combination.

When the acid generator (C) has the form of a low molecular weight compound, the acid generator (C) preferably has a molecular weight of 3000 or less, more preferably 2000 or less, and still more preferably 1000 or less. The lower limit of the molecular weight of the acid generator (C) is not particularly limited, but is preferably 100 or more.

When the acid generator (C) has the form of being incorporated into a portion of a polymer, it may be incorporated into a portion of the resin (A) or may be incorporated into a resin different from the resin (A).

Examples of the acid generator (C) include compounds (onium salts) represented by “M⁺X⁻”, and preferred are compounds that generate organic acids upon exposure. Examples of the organic acids include sulfonic acids (such as aliphatic sulfonic acids, aromatic sulfonic acids, and camphorsulfonic acid), carboxylic acids (such as aliphatic carboxylic acids, aromatic carboxylic acids, and aralkylcarboxylic acids), carbonylsulfonylimidic acid, bis(alkylsulfonyl)imidic acids, and tris(alkylsulfonyl)methide acids.

In such a compound represented by “M⁺X⁻”, M⁺ represents a cation. The cation may be of one species or may be of two or more species. M⁺ preferably represents an organic cation, and the organic cation is not particularly limited. The organic cation is preferably a sulfonium cation, an iodonium cation, or an ammonium cation. The organic cation is more preferably a cation represented by a formula (ZaI) or a cation represented by a formula (ZaII).

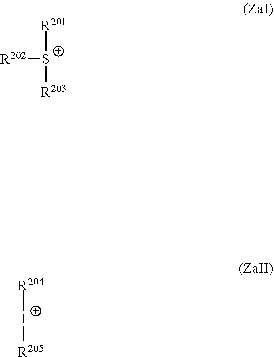

In the formula (ZaI), R²⁰¹, R²⁰², and R²⁰³ each independently represent an organic group.

For R²⁰¹, R²⁰², and R²⁰³, the organic group preferably has 1 to 30 carbon atoms, and more preferably 1 to 20 carbon atoms. Among R²⁰¹ to R²⁰³, two may be bonded together to form a ring structure and the ring may include an oxygen atom, a sulfur atom, an ester group, an amide group, or a carbonyl group. Examples of the group formed by bonding together two of R²⁰¹ to R²⁰³ include alkylene groups (such as a butylene group and a pentylene group), and —CH₂—CH₂—O—CH₂—CH₂—.

For R²⁰¹, R²⁰², and R²⁰³, the organic group is preferably an alkyl group, a cycloalkyl group, an aryl group, or a heteroaryl group.

The alkyl group may be either linear or branched. The number of carbon atoms of the alkyl group is not particularly limited, but is preferably 1 to 10, and more preferably 1 to 5. Examples of the alkyl group include a methyl group, an ethyl group, an n-propyl group, an isopropyl group, an n-butyl group, an isobutyl group, and a t-butyl group.

The number of carbon atoms of the cycloalkyl group is not particularly limited, but is preferably 3 to 20, and more preferably 5 to 15. The cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The aryl group is preferably an aryl group having 6 to 20 carbon atoms, more preferably an aryl group having 6 to 15 carbon atoms, still more preferably a phenyl group or a naphthyl group, and particularly preferably a phenyl group.

The heteroaryl group is preferably a heteroaryl group having 3 to 20 carbon atoms. The heteroaryl group preferably includes at least one heteroatom selected from the group consisting of an oxygen atom, a sulfur atom, and a nitrogen atom. The heteroaryl group may be, for example, a group in which any one hydrogen atom is removed from pyrrole, furan, thiophene, indole, benzofuran, benzothiophene, or the like.

In the formula (ZaII), R²⁰⁴ and R²⁰⁵ each independently represent an aryl group, a heteroaryl group, an alkyl group, or a cycloalkyl group.

For R²⁰⁴ and R²⁰⁵, the aryl group is preferably an aryl group having 6 to 20 carbon atoms, more preferably a phenyl group or a naphthyl group, and still more preferably a phenyl group.

For R²⁰⁴ and R²⁰⁵, the heteroaryl group is preferably a heteroaryl group having 3 to 20 carbon atoms. The heteroaryl group preferably includes at least one heteroatom selected from the group consisting of an oxygen atom, a sulfur atom, and a nitrogen atom. The heteroaryl group may be, for example, a group in which any one hydrogen atom is removed from pyrrole, furan, thiophene, indole, benzofuran, benzothiophene, or the like.

For R²⁰⁴ and R²⁰⁵, the alkyl group and the cycloalkyl group are preferably a linear alkyl group having 1 to 10 carbon atoms, a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

For R²⁰⁴ and R²⁰⁵, the aryl group, the heteroaryl group, the alkyl group, and the cycloalkyl group may each independently have a substituent. For R²⁰⁴ and R²⁰⁵, examples of the substituents that the aryl group, the heteroaryl group, the alkyl group, and the cycloalkyl group may have include alkyl groups (for example, having 1 to 15 carbon atoms), cycloalkyl groups (for example, having 3 to 15 carbon atoms), aryl groups (for example, having 6 to 15 carbon atoms), alkoxy groups (for example, having 1 to 15 carbon atoms), halogen atoms, a hydroxy group, and a phenylthio group. For R²⁰⁴ and R²⁰⁵, substituents are also preferably provided independently as appropriate combinations of substituents to form acid-decomposable groups.

For the cation represented by M⁺, the contents of [0181] to [0205] of WO2022/172715A can be referred to.

In the compound represented by “M⁺X⁻”, X⁻ represents an anion. The anion may be of one species, or may be of two or more species. X⁻ is preferably an organic anion. The organic anion is not particularly limited, but may be a mono-, di-, or higher valent organic anion. The organic anion is preferably an anion that has a very low capability of causing a nucleophilic reaction, and more preferably a non-nucleophilic anion. Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl)methide anions.

In such an aliphatic sulfonate anion or aliphatic carboxylate anion, the aliphatic moiety may be a linear or branched alkyl group or may be a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms, and may be, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxyl group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group.

The sulfonylimide anion may be, for example, a saccharin anion.

In such a bis(alkylsulfonyl)imide anion or a tris(alkylsulfonyl)methide anion, the alkyl groups are preferably an alkyl group having 1 to 5 carbon atoms. In such an alkyl group, a substituent may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

Other examples of the non-nucleophilic anion include phosphorus fluoride (for example, PF₆⁻), boron fluoride (for example, BF₄⁻), and antimony fluoride (for example, SbF₆⁻).

The non-nucleophilic anion is preferably an aliphatic sulfonate anion in which at least the a position of sulfonic acid is substituted with a fluorine atom, an aromatic sulfonate anion substituted with a fluorine atom or a group having a fluorine atom, a bis(alkylsulfonyl)imide anion in which the alkyl groups are substituted with fluorine atoms, or a tris(alkylsulfonyl)methide anion in which the alkyl groups are substituted with fluorine atoms. In particular, the anion is more preferably a perfluoroaliphatic sulfonate anion (preferably having 4 to 8 carbon atoms) or a benzenesulfonate anion having a fluorine atom, and still more preferably a nonafluorobutanesulfonate anion, a perfluorooctanesulfonate anion, pentafluorobenzenesulfonate anion, or a 3,5-bis(trifluoromethyl)benzenesulfonate anion.

The non-nucleophilic anion is also preferably an anion represented by the following formula (AN1).

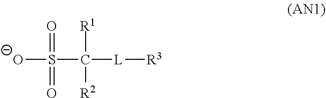

In the formula (AN1), R¹ and R² each independently represent a hydrogen atom or a substituent.

The substituent is not particularly limited, but is preferably a group that is not electron-withdrawing groups. Examples of the group that is not electron-withdrawing groups include hydrocarbon groups, a hydroxy group, oxyhydrocarbon groups, oxycarbonylhydrocarbon groups, an amino group, hydrocarbon-substituted amino groups, and hydrocarbon-substituted amide groups.

Such groups that are not electron-withdrawing groups are each independently preferably —R′, —OH, —OR′, —OCOR′, —NH₂, —NR′₂, —NHR′, or —NHCOR′. R′ are monovalent hydrocarbon groups.

L represents a divalent linking group.

When a plurality of L's are present, L's may be the same or different.

The divalent linking group may be, for example, —O—CO—O—, —COO—, —CONH—, —CO—, —O—, —S—, —SO—, —O₂—, an alkylene group (preferably having 1 to 6 carbon atoms), a cycloalkylene group (preferably having 3 to 15 carbon atoms), an alkenylene group (preferably having 2 to 6 carbon atoms), or a divalent linking group that is a combination of a plurality of the foregoing. In particular, the divalent linking group is preferably —O—CO—O—, —COO—, —CONH—, —CO—, —O—, —SO₂—, —O—CO—O-alkylene group-, —COO-alkylene group-, or —CONH-alkylene group-, and more preferably —O—CO—O—, —O—CO—O-alkylene group-, —COO—, —CONH—, —SO₂—, or —COO-alkylene group-.

In the formula (AN1), R³ represents an organic group.

The organic group is not particularly limited as long as it has 1 or more carbon atoms, and may be a linear group (for example, a linear alkyl group) or a branched group (for example, a branched alkyl group such as a t-butyl group), or may be a cyclic group. The organic group may have or may not have a substituent. The organic group may have or may not have a heteroatom (such as an oxygen atom, a sulfur atom, and/or a nitrogen atom).

In particular, R³ is preferably an organic group having a ring structure. The ring structure may be monocyclic or polycyclic, and may have a substituent. In the organic group including a ring structure, the ring is preferably directly bonded to L in the formula (AN1).

The organic group having a ring structure, for example, may have or may not have a heteroatom (such as an oxygen atom, a sulfur atom, and/or a nitrogen atom). The heteroatom may substitute one or more carbon atoms forming the ring structure.

The organic group having a ring structure is preferably, for example, a hydrocarbon group having a ring structure, a lactone ring group, or a sultone ring group. In particular, the organic group having a ring structure is preferably a hydrocarbon group having a ring structure.

The hydrocarbon group having a ring structure is preferably a monocyclic or polycyclic cycloalkyl group. Such groups may have a substituent.

The cycloalkyl group may be monocyclic (such as a cyclohexyl group) or polycyclic (such as an adamantyl group), and preferably has 5 to 12 carbon atoms.

The non-nucleophilic anion may be a benzenesulfonate anion, and is preferably a benzenesulfonate anion substituted with a branched alkyl group or a cycloalkyl group.

The non-nucleophilic anion is also preferably an anion represented by the following formula (AN2).

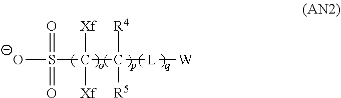

In the formula (AN2), o represents an integer of 1 to 3. p represents an integer of 0 to 10. q represents an integer of 0 to 10.

Xf's represent a hydrogen atom, a fluorine atom, an alkyl group substituted with at least one fluorine atom, or an organic group not having fluorine atoms. The alkyl group preferably has 1 to 10 carbon atoms, and more preferably 1 to 4 carbon atoms. The alkyl group substituted with at least one fluorine atom is preferably a perfluoroalkyl group.

Xf's are preferably a fluorine atom or a perfluoroalkyl group having 1 to 4 carbon atoms, and more preferably a fluorine atom or CF₃; still more preferably, both of Xf's are fluorine atoms.

R⁴ and R⁵ each independently represent a hydrogen atom, a fluorine atom, an alkyl group, or an alkyl group substituted with at least one fluorine atom. When a plurality of R⁴'s and a plurality of R⁵'s are present, R⁴'s and R⁵'s may be individually the same or different.

For R⁴ and R⁵, the alkyl group preferably has 1 to 4 carbon atoms. The alkyl group may have a substituent. R⁴ and R⁵ are preferably a hydrogen atom.

L represents a divalent linking group. The descriptions, specific examples, and preferred ranges of L are the same as those of L in the formula (AN1).

W represents an organic group, preferably represents an organic group including a cyclic structure, and is more preferably a cyclic organic group.

The cyclic organic group may be, for example, an alicyclic group, an aryl group, or a heterocyclic group.

The alicyclic group may be monocyclic or may be polycyclic. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. In particular, preferred are alicyclic groups having a bulky structure having 7 or more carbon atoms such as a norbornyl group, a tricyclodecanyl group, a tetracyclodecanyl group, a tetracyclododecanyl group, and an adamantyl group.

The aryl group may be monocyclic or polycyclic. Examples of the aryl group include a phenyl group, a naphthyl group, a phenanthryl group, and an anthryl group.

The heterocyclic group may be monocyclic or polycyclic. In particular, in the case of a polycyclic heterocyclic group, diffusion of acid can be further suppressed. The heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. In the heterocyclic group, the heterocycle is preferably a furan ring, a thiophene ring, a pyridine ring, or a decahydroisoquinoline ring.

The cyclic organic group may have a substituent. The substituent may be, for example, an alkyl group (that may be linear or branched and preferably has 1 to 12 carbon atoms), a cycloalkyl group (that may have a monocycle, a polycycle, or a spiro ring, and preferably has 3 to 20 carbon atoms), an aryl group (preferably having 6 to 14 carbon atoms), a hydroxy group, an alkoxy group, an ester group, an amide group, a urethane group, a ureido group, a thioether group, a sulfonamide group, or a sulfonic acid ester group. Note that a carbon constituting the cyclic organic group (carbon contributing to formation of the ring) may be a carbonyl carbon.

The non-nucleophilic anion is also preferably an aromatic sulfonate anion represented by the following formula (AN3).

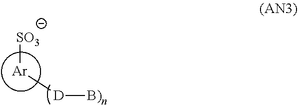

In the formula (AN3), Ar represents an aryl group (such as a phenyl group), and may further have a substituent other than the sulfonate anion and the -(D-B) group. Examples of the substituent that Ar may further have include a fluorine atom and a hydroxy group.

n represents an integer of 0 or more. n is preferably 1 to 4, more preferably 2 to 3, and still more preferably 3.

D represents a single bond or a divalent linking group. The divalent linking group may be an ether group, a thioether group, a carbonyl group, a sulfoxide group, a sulfo group, a sulfonic acid ester group, an ester group, or a group that is a combination of two or more of the foregoing.

B represents a hydrocarbon group.

B is preferably an aliphatic hydrocarbon group, and more preferably an isopropyl group, a cyclohexyl group, or an aryl group that may further have a substituent (such as a tricyclohexylphenyl group).

The non-nucleophilic anion is also preferably a disulfonamide anion.

The disulfonamide anion is, for example, an anion represented by N⁻(SO₂—R^{q})₂.

R^{q}'s represent an alkyl group that may have a substituent, and are preferably a fluoroalkyl group, and more preferably a perfluoroalkyl group. Two R^{q}'s may be bonded together to form a ring. The group formed by bonding together two R^{q}'s is preferably an alkylene group that may have a substituent, preferably a fluoroalkylene group, and more preferably a perfluoroalkylene group. The alkylene group preferably has 2 to 4 carbon atoms.

The acid generator (C) may be at least one selected from the group consisting of compounds (I) to (II).

### Compound (I)

The compound (I) is a compound having one or more structural moieties X described below and one or more structural moieties Y described below, and is a compound that generates, upon irradiation with an actinic ray or a radiation, an acid including a first acidic moiety described below derived from the structural moiety X described below and a second acidic moiety described below derived from the structural moiety Y described below.

Structural moiety X: a structural moiety that is constituted by an anionic moiety A₁⁻ and a cationic moiety M₁⁺ and that forms, upon irradiation with an actinic ray or a radiation, the first acidic moiety represented by HA₁

Structural moiety Y: a structural moiety that is constituted by an anionic moiety A₂⁻ and a cationic moiety M₂⁺ and that forms, upon irradiation with an actinic ray or a radiation, the second acidic moiety represented by HA₂

The compound (I) satisfies the following condition I.

Condition I: A compound PI in which the cationic moiety M₁⁺ in the structural moiety X and the cationic moiety M₂⁺ in the structural moiety Y in the compound (I) are replaced by H⁺ has an acid dissociation constant a1 derived from an acidic moiety represented by HA₁ in which the cationic moiety M₁⁺ in the structural moiety X is replaced by H⁺, and an acid dissociation constant a2 derived from an acidic moiety represented by HA₂ in which the cationic moiety M₂⁺ in the structural moiety Y is replaced by H⁺, and the acid dissociation constant a2 is larger than the acid dissociation constant a1.

At least one acid dissociation constant a1 is 1.0 or less. The acid dissociation constant a2 may be 1.0 or less, or may be more than 1.0.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA₂”.

The acid dissociation constant a1 and the acid dissociation constant a2 of the compound PI will be more specifically described as follows: in determination of the acid dissociation constants of the compound PI, the pKa at the time when the compound PI turns into a “compound having A₁⁻ and HA₂” is the acid dissociation constant a1, and the pKa at the time when the “compound having A₁⁻ and HA₂” turns into a “compound having A₁⁻ and A₂⁻” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA₂”.

In determination of the acid dissociation constants of the compound PI, the acid dissociation constant at the time when the compound PI turns into a “compound having one A₁⁻, one HA₁, and one HA₂” and the acid dissociation constant at the time when the “compound having one A₁⁻, one HA₁, and one HA₂” turns into a “compound having two A₁⁻ and one HA₂” correspond to the above-described acid dissociation constant a1. The acid dissociation constant at the time when the “compound having two A₁⁻ and one HA₂” turns into a “compound having two A₁⁻ and A₂⁻” corresponds to the acid dissociation constant a2. In other words, when the compound PI has a plurality of acid dissociation constants derived from the acidic moieties represented by HA₁ in which the cationic moiety M₁⁺ in the structural moiety X is replaced by H⁺, the value of the acid dissociation constant a2 is larger than the largest value of the plurality of the acid dissociation constants a1. Note that, in a case where the acid dissociation constant at the time when the compound PI turns into the “compound having one A₁⁻, one HA₁, and one HA₂” is defined as aa, and the acid dissociation constant at the time when the “compound having one A₁⁻, one HA₁, and one HA₂” turns into the “compound having two A₁⁻ and one HA₂” is defined as ab, the relationship between aa and ab satisfies aa<ab.

The acid dissociation constant a1 and the acid dissociation constant a2 can be determined by the above-described method of measuring an acid dissociation constant.

The compound PI corresponds to an acid generated upon irradiation of the compound (I) with an actinic ray or a radiation.

When the compound (I) has two or more structural moieties X, the structural moieties X may be the same or different. The two or more A₁⁻ and the two or more M₁⁺ may be individually the same or different.

In the compound (I), A₁⁻ above and A₂⁻ above, and M₁⁺ above and M₂⁺ above may be individually the same or different, but A₁⁻ above and A₂⁻ above are preferably different from each other.

In the compound PI, the difference (absolute value) between the acid dissociation constant a1 (when a plurality of acid dissociation constants a1 are present, the maximum value thereof) and the acid dissociation constant a2 is preferably 0.1 or more, more preferably 0.5 or more, and still more preferably 1.0 or more. Note that the upper limit value of the difference (absolute value) between the acid dissociation constant a1 (when a plurality of acid dissociation constants a1 are present, the maximum value thereof) and the acid dissociation constant a2 is not particularly limited, but is, for example, 16 or less.

In the compound PI, the acid dissociation constant a2 is preferably 20 or less, and more preferably 15 or less. The lower limit value of the acid dissociation constant a2 is preferably −4 or more.

The cationic moiety M₁⁺ and the cationic moiety M₂⁺ are structural moieties including a positively charged atom or atomic group, and examples thereof include singly charged cations. Examples of the cations include the above-described cations represented by M⁺.

### Compound (II)

A compound (II) is a compound having two or more structural moieties X above and one or more structural moieties Z below, and is a compound that generates, upon irradiation with an actinic ray or a radiation, an acid including two or more first acidic moieties derived from the structural moieties X and the structural moiety Z.

### Structural Moiety Z: a Nonionic Moiety That Can Neutralize Acid

In the compound (II), the definition of the structural moiety X and the definitions of A₁⁻ and M₁⁺ are the same as the definition of the structural moiety X and the definitions of A₁⁻ and M₁⁺ in the above-described compound (I), and preferred examples are also the same.

In a compound PII in which the cationic moiety M₁⁺ in the structural moiety X in the compound (II) is replaced by H⁺, the preferred range of the acid dissociation constant a1 derived from the acidic moiety represented by HA₁ in which the cationic moiety M₁⁺ in the structural moiety X is replaced by H⁺ is the same as in the acid dissociation constant a1 in the compound PI.

At least one acid dissociation constant a1 is 1.0 or less.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A⁻ and one HA₁” and the acid dissociation constant at the time when the “compound having one A₁⁻ and one HA₁” turns into a “compound having two A₁⁻” correspond to the acid dissociation constant a1.

The acid dissociation constant a1 can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁⁻ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to x-conjugation. Examples of the nitrogen atom having an unshared electron pair that does not contribute to x-conjugation include nitrogen atoms having partial structures represented by the following formulas.

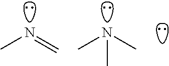

### Unshared Electron Pair

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

For the compound (I) and the compound (II), the descriptions in [0175] to [0280] of WO2022/024928A can be referred to.

The content of the acid generator (C) in the composition of the present invention is, relative to the total solid content of the composition of the present invention, preferably 0.5 mass % or more, and more preferably 1.0 mass % or more. The content of the acid generator (C) is, relative to the total solid content of the composition of the present invention, preferably 50.0 mass % or less, more preferably 30.0 mass % or less, and still more preferably 25.0 mass % or less.

Such acid generators (C) may be used alone or in combination of two or more thereof. When two or more acid generators (C) are used, the total content thereof is preferably within such a preferred content range.

The total amount of the acid generator (C) (T_{C}) relative to the total solid content of the composition of the present invention is preferably 0.40 mmol/g or more and 1.50 mmol/g or less, preferably 0.40 mmol/g or more and 1.50 mmol/g or less, more preferably 0. 50 mmol/g or more and 1.50 mmol/g or less, and still more preferably 0.60 mmol/g or more and 1.50 mmol/g or less. T_{C} (mmol/g) is the total substance amount (mmol) of the acid generator (C) included in 1 g of the total solid content of the composition of the present invention.

When a resin such as the resin (A) includes a repeating unit having a photoacid generation group, T_{C} is calculated such that a value obtained by multiplying the substance amount of the resin by the molar fraction of the repeating unit having a photoacid generation group is included in the substance amount of the acid generator (C).

### Acid Diffusion Control Agent (D)

The acid diffusion control agent (D) included in the composition of the present invention will be described.

The acid diffusion control agent (D) can serve as a quencher that traps the acid generated from the photoacid generator (for example, the acid generator (C)) or the like during exposure and that suppresses the reaction of, caused by an excess of generated acid, the acid-decomposable resin in the unexposed region.

The type of the acid diffusion control agent (D) is not particularly limited, and examples thereof include a basic compound (DA), a low molecular weight compound (DB) having a nitrogen atom and having a group that leaves by the action of an acid, and a compound (DC) whose acid diffusion control ability is reduced or lost upon irradiation with an actinic ray or a radiation.

Examples of the compound (DC) include an onium salt compound (DD) of an acid that becomes a weak acid relative to the acid generated from the photoacid generator (for example, the acid generator (C)), and a basic compound (DE) whose basicity is reduced or lost upon irradiation with an actinic ray or a radiation.

Specific examples of the basic compound (DA) include, for example, those described in Paragraphs [0132] to [0136] of WO2020/066824A; specific examples of the basic compound (DE) whose basicity is reduced or lost upon irradiation with an actinic ray or a radiation include those described in Paragraphs [0137] to [0155] of WO2020/066824A, and those described in Paragraph [0164] of WO2020/066824A; specific examples of the low molecular weight compound (DB) having a nitrogen atom and having a group that leaves by the action of an acid include those described in Paragraphs [0156] to [0163] of WO2020/066824A.

Specific examples of the onium salt compound (DD) that becomes a weak acid relative to the photoacid generator include, for example, those described in Paragraphs [0305] to [0314] of WO2020/158337A.

In addition to those described above, for example, the publicly known compounds disclosed in Paragraphs [0627] to [0664] in US2016/0070167A1, Paragraphs [0095] to [0187] in US2015/0004544A1, Paragraphs [0403] to [0423] in US2016/0237190A1, and Paragraphs [0259] to [0328] in US2016/0274458A1 can be suitably used as acid diffusion control agents.

When the acid diffusion control agent (D) is a compound that generates an acid upon irradiation with an actinic ray or a radiation, the acid generated from the acid diffusion control agent (D) (generated acid) preferably has a pKa of more than 1.0.

When the pKa of the generated acid from the acid diffusion control agent (D) is defined as pKa(D) and the pKa of the generated acid from the acid generator (C) is defined as pKa(C), pKa(D)−pKa(C) is preferably 1.0 or more, more preferably 2.0 or more, and still more preferably 3.0 or more.

The acid diffusion control agent (D) is preferably an ionic compound composed of an anion and a cation. Examples of the cation include the same cations as M⁺ described above. The anion is preferably at least one selected from the group consisting of an anion represented by the following formula (Dn-1), an anion having a group represented by the following formula (Dn-2), an anion having a group represented by the following formula (Dn-3), an anion having a group represented by the following formula (Dn-4), and an anion having a group represented by the following formula (Dn-5).

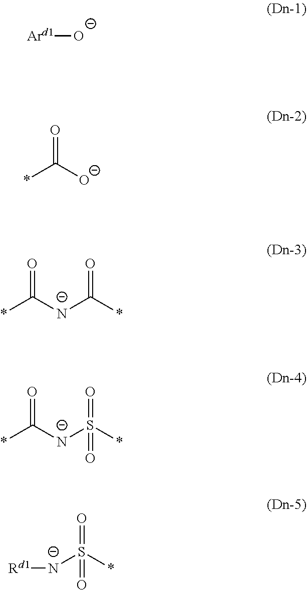

In the formulas (Dn-2), (Dn-3), (Dn-4), and (Dn-5), * each represent a bonding site. In the formula (Dn-1), Ar^{d1} represents an aromatic group. In the formula (Dn-5), R^{d1} represents a hydrogen atom or a monovalent organic group.

Ar^{d1} is preferably an aryl group, more preferably an aryl group having 6 to 20 carbon atoms, and most preferably a phenyl group.

For R^{d1}, the monovalent organic group is, for example, an alkyl group (preferably an alkyl group having 1 to 10 carbon atoms), a cycloalkyl group (preferably a cycloalkyl group having 3 to 20 carbon atoms), or an aryl group (preferably an aryl group having 6 to 20 carbon atoms).

The acid diffusion control agent (D) is also preferably a compound including a functional group having a nitrogen atom having an unshared electron pair that does not contribute to π-conjugation. The nitrogen atom having an unshared electron pair that does not contribute to π-conjugation is as described above. Examples of the functional group having a nitrogen atom having an unshared electron pair that does not contribute to π-conjugation include primary to tertiary amine structures, pyridine structures, imidazole structures, and pyrazine structures.

The content of the acid diffusion control agent (D) in the composition of the present invention relative to the total solid content of the composition of the present invention is preferably 0.1 to 30.0 mass %, and more preferably 1.0 to 25.0 mass %.

Such acid diffusion control agents (D) may be used alone or in combination of two or more thereof. When two or more acid diffusion control agents (D) are used, the total content thereof is preferably within such a preferred content range.

Qp, which is a value obtained by dividing the total substance amount of the acid diffusion control agent (D) included in the composition of the present invention by the total substance amount of the cations included in the composition of the present invention, is preferably 0.40 or more and 1.00 or less.

When the total substance amount (mol) of the acid diffusion control agent (D) included in the composition of the present invention is defined as M_{D}, and the total substance amount (mol) of the cations included in the composition of the present invention is defined as M_{CA}, Qp is represented by the following formula (4). M_{CA} is for all the components that include cations in the composition of the present invention.

$$Qp = {N}_{D} / {M}_{CA} \qquad Formula ( 4 )$$

Particularly preferably, the total amount of the acid generator (C) relative to the total solid content of the composition of the present invention is 0.40 mmol/g or more and 1.50 mmol/g or less, and the Qp is 0.40 or more and 1.00 or less.

Qp is more preferably 0.45 or more and 0.90 or less, and still more preferably 0.50 or more and 0.80 or less.

The W_{B}/Qp, which is a value obtained by dividing the mass-based content ratio W_{B} (mass %) of the resin (B) included in the composition of the present invention, by Qp, is preferably less than 20 mass %, more preferably 15 mass % or less, and particularly preferably 10 mass % or less.

### Hydrophobic Resin

The composition of the present invention can further include a hydrophobic resin. The hydrophobic resin is a resin different from the resin (A) and the resin (B).

The hydrophobic resin is preferably designed so as to be localized in the surface of a resist film; however, unlike surfactants, the hydrophobic resin does not necessarily need to have intramolecularly a hydrophilic group, and does not necessarily contribute to homogeneous mixing of a polar substance and a nonpolar substance.

Advantages due to addition of the hydrophobic resin may be control of static and dynamic contact angles (for water) at the surface of the resist film, and suppression of outgassing.

The hydrophobic resin, from the viewpoint of localization in the surface layer of the film, preferably has one or more species, more preferably two or more species, selected from the group consisting of a fluorine atom, a silicon atom, and a CH₃ moiety included in the side chain moiety of the resin. The hydrophobic resin preferably has a hydrocarbon group having 5 or more carbon atoms. The resin may have such a group in the main chain or, as a substituent, in a side chain.

Examples of the hydrophobic resin include the compounds described in Paragraphs [0275] to [0279] in WO2020/004306A.

When the composition of the present invention includes a hydrophobic resin, the content of the hydrophobic resin relative to the total solid content of the composition of the present invention is preferably 0.01 to 20.0 mass %, and more preferably 0.1 to 15.0 mass %.

Such hydrophobic resins may be used alone, or may be used in combination of two or more thereof. When two or more hydrophobic resins are used, the total content thereof is preferably within such a preferred content range.

### Surfactant

The composition of the present invention may include a surfactant. In the case of including a surfactant, a pattern having higher adhesiveness and a less number of development defects can be formed.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

When the composition of the present invention includes a surfactant, the surfactant content relative to the total solid content of the composition of the present invention is preferably 0.0001 to 2.0 mass %, more preferably 0.0005 to 1.0 mass %, and still more preferably 0.1 to 1.0 mass %.

Such surfactants may be used alone, or may be used in combination of two or more thereof. When two or more surfactants are used, the total content thereof is preferably within such a preferred content range.

### Solvent

The composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

A combination of the above-described solvent and the above-described resin is preferred from the viewpoint of improving the coatability of the composition of the present invention and reducing the number of pattern development defects. The above-described solvent is well-balanced in terms of solubility of the above-described resin, boiling point, and viscosity, to thereby suppress, for example, unevenness of the film thickness of the resist film and generation of deposit during spin-coating.

Details of the component (M1) and the component (M2) are described in Paragraphs [0218] to [0226] in WO2020/004306A, and these contents are incorporated herein by reference.

When the solvent further includes a component other than the components (M1) and (M2), the content of the component other than the components (M1) and (M2) relative to the total amount of the solvent is preferably 5 to 30 mass %.

The content of the solvent in the composition of the present invention is set such that the solid content concentration is preferably 0.5 to 30 mass %, and more preferably 1 to 20 mass %. This further improves the coatability of the composition of the present invention.

### Other Additives

The composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxy group).

The “dissolution-inhibiting compound” is a compound that is decomposed by the action of an acid to cause a decrease in the degree of solubility in organic-based developers, and has a molecular weight of 3000 or less.

The composition of the present invention is particularly suitably used as a photosensitive composition for EB exposure or EUV exposure.

### Actinic Ray-Sensitive or Radiation-Sensitive Film and Pattern Forming Method

The present invention also relates to an actinic ray-sensitive or radiation-sensitive film formed from the composition of the present invention. The actinic ray-sensitive or radiation-sensitive film of the present invention is preferably a resist film.

The procedures of the pattern forming method using the composition of the present invention are not particularly limited, but preferably include a resist film formation step (step 1) of using the composition of the present invention to form a resist film, an exposure step (step 2) of exposing the resist film, and a development step (step 3) of developing the exposed resist film using a developer.

Hereinafter, the procedures of the steps will be described in detail.

### Step 1: Resist Film Formation Step

The step 1 is a step of using the composition of the present invention to form a resist film. The composition of the present invention is used to form a resist film on a substrate preferably.

Examples of the method of using the composition of the present invention to form a resist film on a substrate include a method of applying the composition of the present invention onto a substrate.

Note that the composition of the present invention is preferably filtered through a filter before application as needed. The filter preferably has a pore size of 0.1 μm or less, more preferably 0.05 μm or less, and still more preferably 0.03 μm or less. The filter is preferably formed of polytetrafluoroethylene, polyethylene, or nylon.

The composition of the present invention can be applied onto a substrate (such as a silicon, silicon dioxide-covered substrate) used in the production of an integrated circuit element, by an appropriate application process using a spinner, a coater, or the like. The application process is preferably spin-coating using a spinner. The spin-coating using a spinner is preferably performed at a rotation rate of 1000 to 3000 rpm (rotations per minute).

After application of the composition of the present invention, the substrate may be dried to form a resist film. Note that, as needed, as underlayers of the resist film, various underlying films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the resist film is not particularly limited, but is, from the viewpoint of enabling formation of more precise fine patterns, preferably 10 to 120 nm. In particular, when EB exposure or EUV exposure is performed, the resist film has a film thickness of more preferably 10 to 65 nm, still more preferably 15 to 50 nm. In the case of employing ArF liquid immersion exposure, the film thickness of the resist film is more preferably 10 to 120 nm, and still more preferably 15 to 90 nm.

Note that, for an overlying layer of the resist film, a topcoat composition may be used to form a topcoat.

The topcoat composition preferably does not mix with the resist film, and can be uniformly applied for an overlying layer of the resist film. The topcoat is not particularly limited; a publicly known topcoat can be formed by a publicly known process; for example, on the basis of descriptions of Paragraphs [0072] to [0082] in JP2014-059543A, a topcoat can be formed.

For example, a topcoat including a basic compound and described in JP2013-61648A is preferably formed on the resist film. Specific examples of the basic compound that can be included in the topcoat include basic compounds that may be included in the composition of the present invention.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the resist film.

The exposure process may be a process of irradiating the formed resist film, through a predetermined mask, with an actinic ray or a radiation.

Examples of the actinic ray or the radiation include infrared light, visible light, ultraviolet light, far-ultraviolet light, extreme ultraviolet light, X-rays, and electron beams; preferred is 250 nm or less; more preferred is 220 nm or less; particularly preferred are far-ultraviolet light having wavelengths of 1 to 200 nm, specifically, KrF excimer laser (248 nm), ArF excimer laser (193 nm), F₂ excimer laser (157 nm), and EUV (13.5 nm), X-rays, and electron beams.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

### Step 3: Development Step

The step 3 is a step of using a developer to develop the exposed resist film, to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less.

### Other Step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and may be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition and the pattern forming method of the present invention (for example, a solvent, a developer, a rinse liquid, an antireflection film-forming composition, and a topcoat-forming composition) preferably do not include impurities such as metals. The content of impurities included in such materials is preferably 1 mass ppm (parts per million) or less, more preferably 10 mass ppb (parts per billion) or less, still more preferably 100 mass ppt (parts per trillion) or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph [0321] in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter may be used in combination with an adsorption material. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used. Method for producing electronic device

This Specification also relates to a method for producing an electronic device, the method including the above-described pattern forming method, and an electronic device produced by the production method.

The electronic device in this Specification is, in a preferred embodiment, mounted on electric or electronic devices (such as household appliances, OA (Office Automation), media-related devices, optical devices, and communication devices).

### EXAMPLES

Hereinafter, the present invention will be described further in detail with reference to Examples. In the following Examples, materials, usage amounts, ratios, details of treatments, and orders of treatments can be appropriately changed without departing from the spirit and scope of the present invention. Thus, the scope of the present invention should not be construed as being limited to the following Examples.

Various components used in the resist compositions of Examples and Comparative Examples will be described below.

### Resin (A)

The resin (A) employed were A-1 to A-6. For A-1 to A-6, structural formulas, weight-average molecular weights (Mw), and dispersities (Mw/Mn) will be described below. The content ratios of repeating units below (contents relative to all the repeating units in the resins) are molar ratios. Mw and Mw/Mn were measured by GPC (carrier: tetrahydrofuran (THF)) (polystyrene-equivalent amounts). The contents of the repeating units were measured by ¹³C-NMR (nuclear magnetic resonance).

A-6, which includes a repeating unit having a photoacid generation group and also corresponds to the acid generator (C), will be described, in Table 1 below, only in the column of Resin (A) and is not described in the column of Acid generator (C).

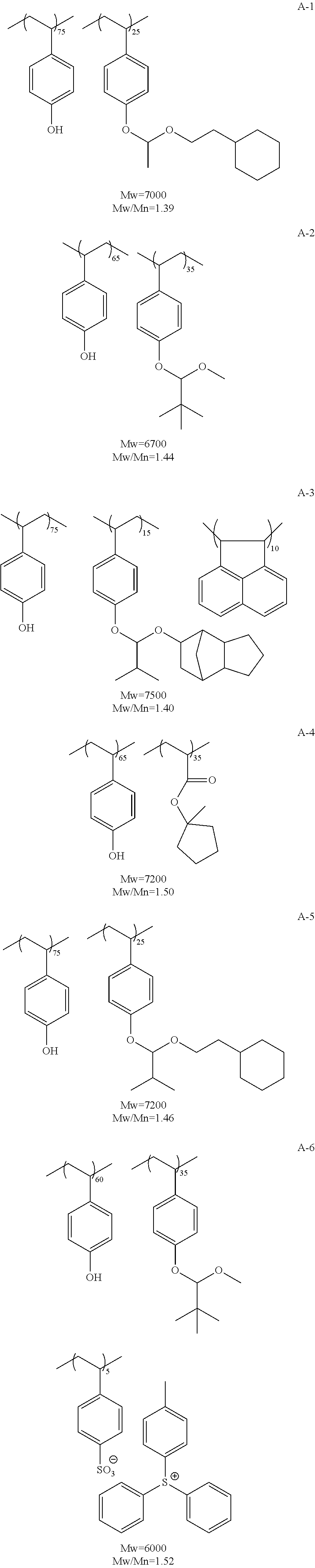

### Resin (B)

The resin (B) employed were B-1 to B-15. In addition, as resins other than the resin (B), BX-1 to B-X4 were used. For convenience, Table 1 below describes BX-1 to B-X4 also in the column of Resin (B). For B-1 to B-15 and BX-1 to B-X4, structural formulas, weight-average molecular weights (Mw), and dispersities (Mw/Mn) will be described below. The content ratios of repeating units below (contents relative to all the repeating units in the resins) are molar ratios. Mw and Mw/Mn were measured by GPC (carrier: THF) (polystyrene-equivalent amounts). The contents of the repeating units were measured by ¹³C-NMR.

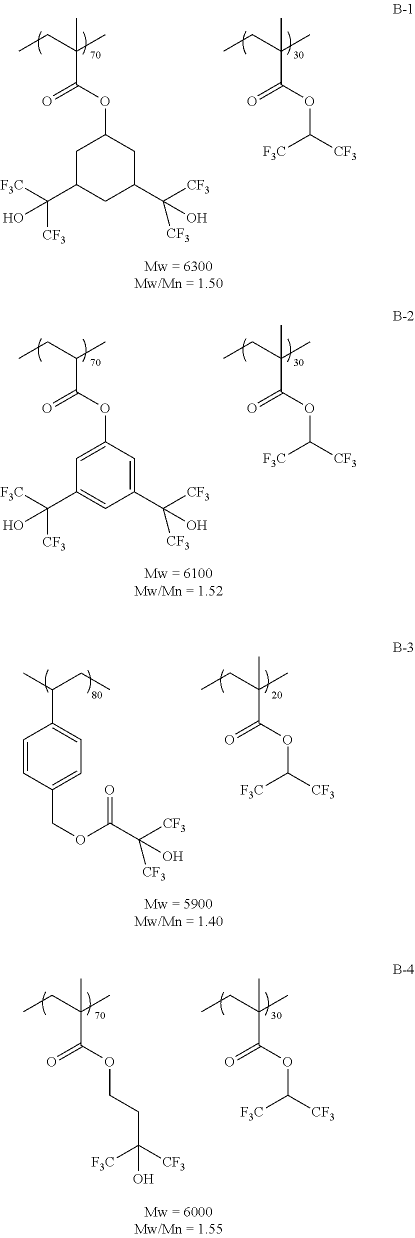

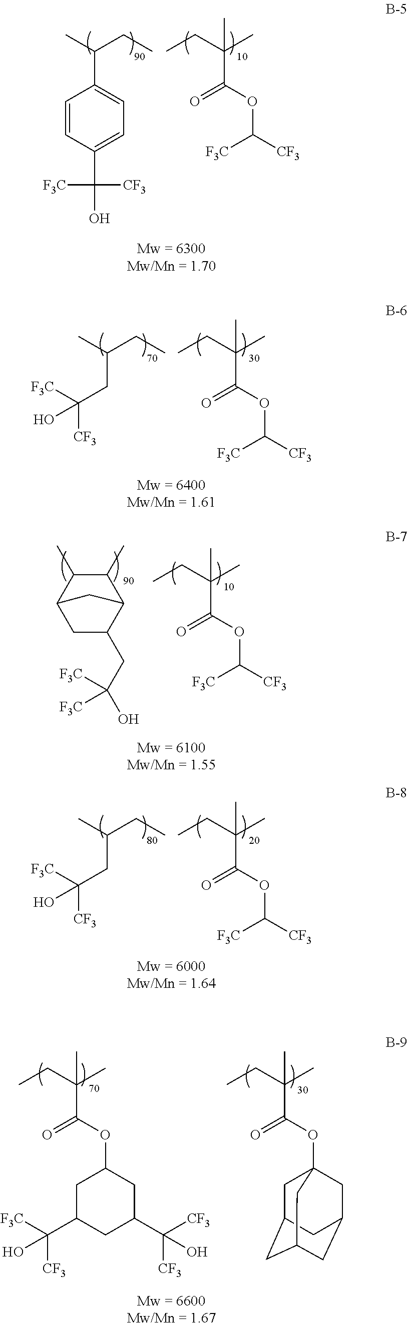

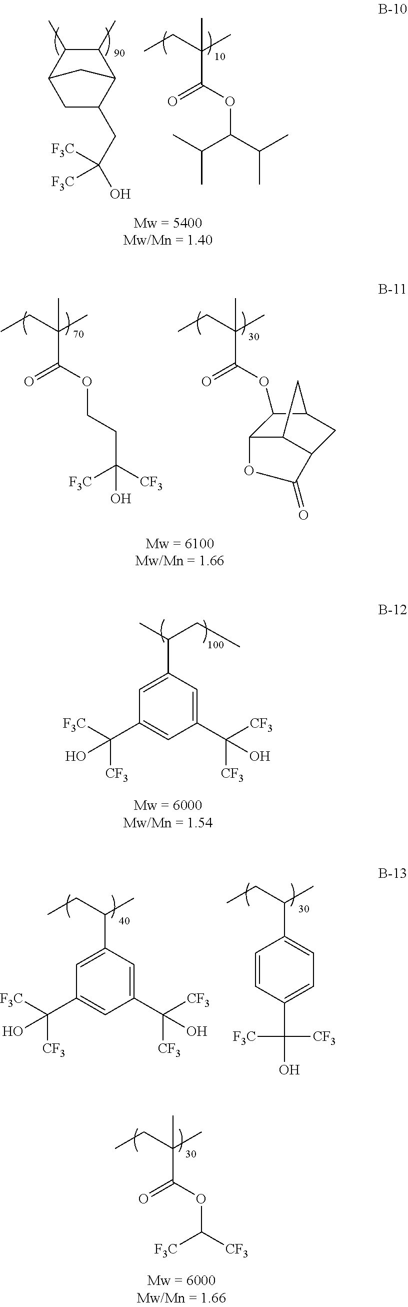

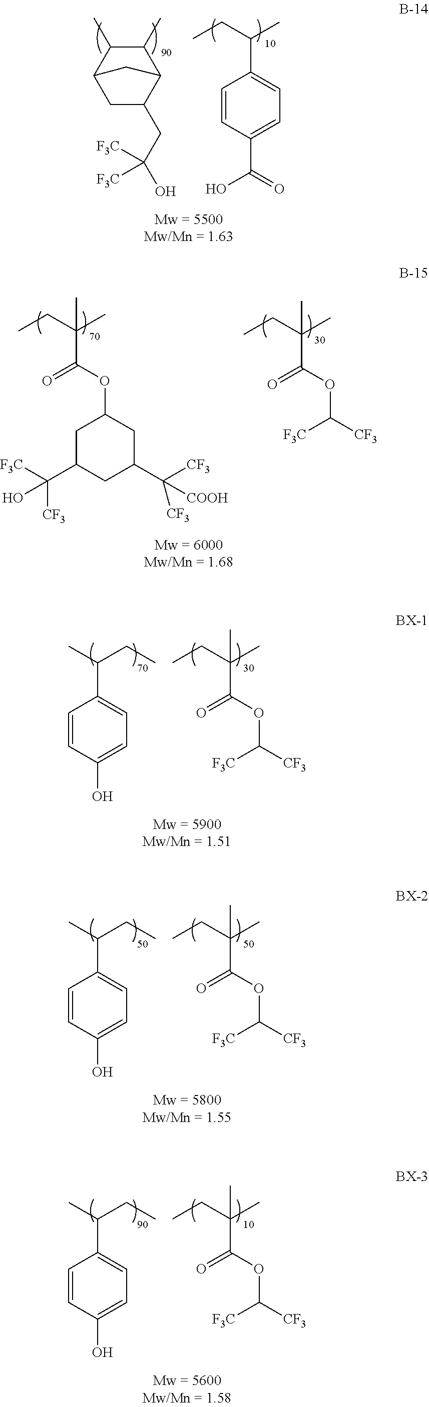

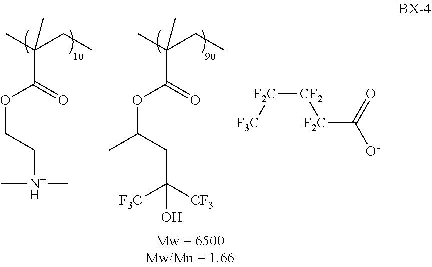

### Synthesis of Resin B-1

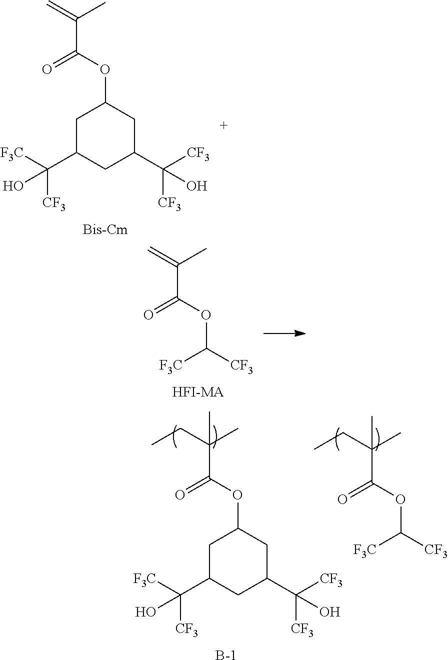

First, 8.98 g of a compound (Bis-Cm), 2.83 g of a compound (HFI-MA), and 0.69 g of a polymerization initiator V-601 (manufactured by FUJIFILM Wako Pure Chemical Corporation) were dissolved in 19.94 g of cyclohexanone. To a reaction vessel, 8.29 g of cyclohexanone was added; under a nitrogen gas atmosphere, to the system at 80° C., dropwise addition was performed over 6 hours. The reaction solution was heated and stirred for 2 hours, and subsequently, this was allowed to cool to room temperature.

The reaction solution was added dropwise to 276 g of methanol/water=5/5 (mass ratio) to precipitate a polymer, and filtration was performed. The solid obtained by the filtration was rinsed with 40 g of methanol/water=5/5 (mass ratio). Subsequently, the post-rising solid was subjected to drying under a reduced pressure to obtain 6.40 g of a resin B-1.

The obtained resin B-1 had a weight-average molecular weight of 6300 and a compositional ratio of (repeating unit derived from Bis-Cm)/(repeating unit derived from HFI-MA)=70/30 (molar ratio).

### Acid Generator (C)

The acid generator (C) employed were C-1 to C-3 represented by structural formulas below. C-1 to C-3 are photoacid generators. The acids generated from C-1 to C-3 upon irradiation with an actinic ray or a radiation (generated acids) will be described below in terms of pKa.

The generated acid from C-1 has a pKa of −0.20.

The generated acid from C-2 has a pKa of −0.20.

The generated acid from C-3 has a pKa of −3.3.

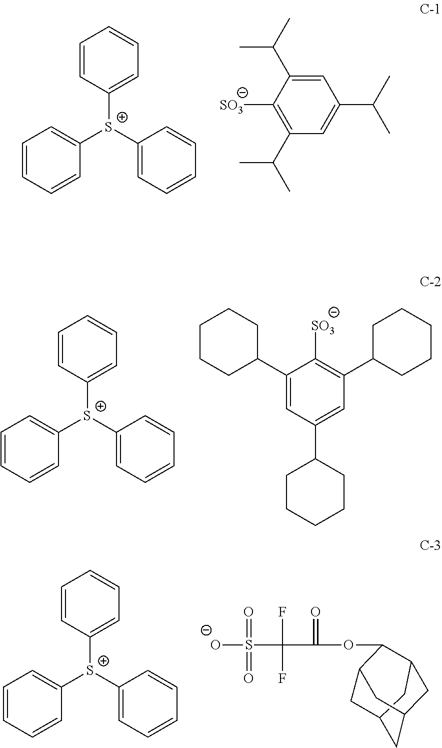

### Acid Diffusion Control Agent (D)

The acid diffusion control agent (D) employed were D-1 to D-4 represented by structural formulas below. D-1 to D-3 are compounds that, upon irradiation with an actinic ray or a radiation, generate an acid weaker than the generated acid from the acid generator (C). The acids generated from D-1 to D-3 (generated acids) and the conjugate acid of D-4 will be described below in terms of pKa.

The generated acid from D-1 has a pKa of 4.79.

The generated acid from D-2 has a pKa of 1.30.

The generated acid from D-3 has a pKa of 3.01.

The conjugate acid of D-4 has a pKa of 5.40.

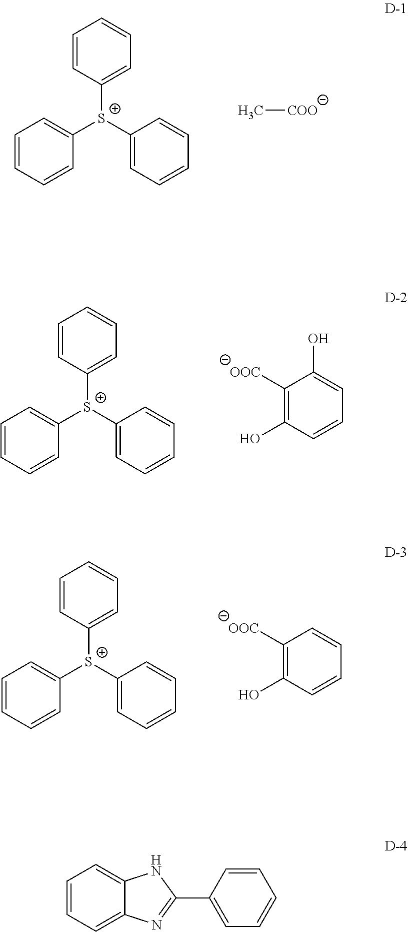

### Solvent

The solvents employed were as follows.
HBM: methyl 2-hydroxyisobutyrate
DAA: diacetone alcohol
EL: ethyl lactate
PGMEA: propylene glycol monomethyl ether acetate
PGME: propylene glycol monomethyl ether
rBL: γ-butyrolactone

### Preparation of Resist Compositions

The components (solid contents) other than the solvents described in Table 1 were used in the contents (mass %) described in Table 1, and mixed with the solvents described in Table 1 to obtain solutions. The contents of the components are mass ratios (mass %) relative to the total solid contents of the resist compositions. The obtained solutions were filtered through polyethylene filters having a pore size of 0.02 μm to obtain resist compositions R-1 to R-16 and RX-1 to RX-4. The solid content concentrations of all the resist compositions were adjusted to 3.0 mass %. The solid contents mean all the components other than the solvent. Table 1 describes the types of solvents employed and the mass ratios thereof.

In the resist composition R-14, as the acid generator (C), two compounds of C-1 and C-2 were used at C-2/C-1=1/1 (mass ratio) in a total of 15.0 mass %.

TABLE 1

| | | | | | | | | Acid diffusion | | |
|---|---|---|---|---|---|---|---|---|---|---|
| | | Resin (A) | | Resin (B) | | Acid generator (C) | | control agent (D) | | |
| | Resist | | Content | | Content | | Content | | Content | Solvent |
| | composition | Type | (mass %) | Type | (mass %) | Type | (mass %) | Type | (mass %) | (mass ratio) |
| Comparative | RX-1 | A-1 | 68.0 | BX-1 | 10.0 | C-1 | 15.0 | D-1 | 7.0 | PGMEA/EL = 8/2 |
| Example 1 | | | | | | | | | | |
| Comparative | RX-2 | A-3 | 67.0 | BX-2 | 10.0 | C-2 | 15.0 | D-2 | 8.0 | PGMEA/PGME = 8/2 |
| Example 2 | | | | | | | | | | |
| Comparative | RX-3 | A-2 | 68.0 | BX-3 | 10.0 | C-2 | 15.0 | D-1 | 7.0 | PGMEA/PGME = 8/2 |
| Example 3 | | | | | | | | | | |
| Comparative | RX-4 | A-1 | 67.0 | BX-4 | 10.0 | C-2 | 15.0 | D-1 | 8.0 | PGMEA/PGME = 8/2 |
| Example 4 | | | | | | | | | | |
| Example 1 | R-1 | A-3 | 65.0 | B-1 | 8.0 | C-1 | 15.0 | D-2 | 12.0 | PGMEA/PGME = 8/2 |
| Example 2 | R-2 | A-2 | 70.0 | B-2 | 5.0 | C-2 | 15.0 | D-1 | 10.0 | PGMEA/PGME/DAA = |
| | | | | | | | | | | 6/2/2 |
| Example 3 | R-3 | A-1 | 65.0 | B-3 | 10.0 | C-2 | 15.0 | D-1 | 10.0 | PGMEA/PGME = 8/2 |
| Example 4 | R-4 | A-1 | 72.0 | B-4 | 3.0 | C-2 | 15.0 | D-3 | 10.0 | PGMEA/PGME = 8/2 |
| Example 5 | R-5 | A-2 | 40.0 | B-5 | 10.0 | C-2 | 30.0 | D-3 | 20.0 | PGMEA/PGME = 8/2 |
| Example 6 | R-6 | A-3 | 70.0 | B-6 | 5.0 | C-1 | 15.0 | D-1 | 10.0 | PGMEA/PGME = 8/2 |
| Example 7 | R-7 | A-2 | 65.0 | B-7 | 10.0 | C-2 | 15.0 | D-1 | 10.0 | PGMEA/PGME = 8/2 |
| Example 8 | R-8 | A-1 | 67.0 | B-8 | 8.0 | C-2 | 15.0 | D-3 | 10.0 | PGMEA/PGME = 8/2 |
| Example 9 | R-9 | A-4 | 67.0 | B-9 | 10.0 | C-3 | 8.0 | D-1 | 15.0 | PGMEA/PGME = 8/2 |
| Example 10 | R-10 | A-3 | 65.0 | B-10 | 10.0 | C-3 | 15.0 | D-2 | 10.0 | PGMEA/PGME = 8/2 |
| Example 11 | R-11 | A-5 | 61.0 | B-12 | 5.0 | C-1 | 30.0 | D-4 | 4.0 | PGMEA/PGME/rBL = |
| | | | | | | | | | | 6/2/2 |
| Example 12 | R-12 | A-1 | 71.0 | B-13 | 10.0 | C-1 | 15.0 | D-4 | 4.0 | PGMEA/PGME = 8/2 |
| Example 13 | R-13 | A-6 | 82.0 | B-11 | 8.0 | — | — | D-1 | 10.0 | PGMEA/PGME/HBM = |
| | | | | | | | | | | 6/2/2 |
| Example 14 | R-14 | A-1 | 65.0 | B-4 | 10.0 | C-2/C-1 | 15.0 | D-3 | 10.0 | PGMEA/PGME = 8/2 |
| Example 15 | R-15 | A-3 | 72.0 | B-14 | 3.0 | C-3 | 15.0 | D-2 | 10.0 | PGMEA/PGME = 8/2 |
| Example 16 | R-16 | A-3 | 68.0 | B-15 | 5.0 | C-1 | 15.0 | D-2 | 12.0 | PGMEA/PGME = 8/2 |

Table 2 below describes Qp, T_{c}, W_{B}/Qp, Ra, P_{B}, and F_{B}.

Qp is, as described above, a value obtained by dividing the total substance amount of the acid diffusion control agent (D) included in the resist composition, by the total substance amount of the cations included in the resist composition.

T_{C} is, as described above, the total substance amount (mmol) of the acid generator (C) relative to 1 g of the total solid content of the resist composition. In Table 2, the unit of T_{C} is “mmol/g”.

W_{B}/Qp is, as described above, a value obtained by dividing the mass-based content ratio W_{B} (mass %) of the resin (B) included in the resist composition, by Qp. In Table 2, the unit of W_{B}/Qp is “mass %”.

Ra is, as described above, the distance between the Hansen solubility parameters of the resin (B) and the Hansen solubility parameters of air. Ra is a value calculated by the above-described formula (2) using the calculation software for HSP values, HSPiP (4th edition, 4.1.07), and using the Hansen solubility parameters (HSP₁) of the resin (B) calculated by the Y-MB method and the Hansen solubility parameters of air (HSP₂) (12.46, 0, 0) calculated by taking the weighted average of HSPs of nitrogen and oxygen described in the manual of HSPip (ver. 4, e-Book Chapter 19). The unit of Ra in Table 2 is “MPa^{0.5}”.

P_{B} is, as described above, the sum of values obtained by multiplying the C log P of each repeating unit included in the resin (B) by the molar fraction of the repeating unit, and is determined by the above-described method.

F_{B} is, as described above, the sum of values obtained by multiplying the value obtained by dividing the number of fluorine atoms in each repeating unit included in the resin (B) by the number of all atoms, by the molar fraction of the repeating unit. In Table 2, the unit of F_{B} is “mol %”.

Note that, for the resin BX-4, Ra, P_{B}, and F_{B} were not calculated.

### Application of Resist Composition

The prepared resist composition was applied onto a 6-inch Si (silicon) wafer that had been subjected to hexamethyldisilazane (HMDS) treatment in advance, using a spin coater Mark8 manufactured by Tokyo Electron Ltd., and dried on a hot plate at 130° C. for 300 seconds to obtain a resist film having a film thickness of 100 nm.

Note that, even in the case of changing the Si wafer to a chromium substrate, similar results are obtained.

### Pattern Forming Method (1): EB Exposure, Alkali Development (Positive)

The wafer obtained above and coated with the resist film was subjected to pattern irradiation using an electron beam lithography apparatus (manufactured by ADVANTEST CORPORATION; F7000S, accelerating voltage: 50 kev). After the electron beam lithography, the wafer was heated on a hot plate at 100° C. for 60 seconds, immersed in a 2.38 mass % aqueous solution of tetramethylammonium hydroxide (TMAH) for 60 seconds, subsequently rinsed with water for 30 seconds, and dried. Subsequently, the wafer was rotated at a number of rotations of 4000 rpm for 30 seconds, and subsequently baked at 95° C. for 60 seconds for drying.

### Evaluation

### Resolution

The profile of the obtained pattern was observed using a scanning electron microscope (manufactured by Hitachi, Ltd., S-9380II). The exposure dose (electron beam irradiation dose) at which a resist pattern of a trench pattern (isolated space) having a trench having a width of 50 nm and formed at a pitch of 300 nm was resolved was defined as the sensitivity (Eop).

The limit of resolution (the width of the minimum trench to be resolved) at an exposure dose at which the above-described sensitivity was provided was defined as the resolution (nm). The smaller this value, the higher the resolution.

Table 2 below describes the resist compositions used in Examples and Comparative Examples, and the results of Examples and Comparative Examples.

TABLE 2

| | Qp | T_{C} | W_{B}/Qp | Ra | P_{B} | F_{B} | Resolution |
|---|---|---|---|---|---|---|---|
| Comparative | 0.44 | 0.49 | 22.6 | 35.9 | 0.23 | 8.6% | 35.0 |
| Example 1 | | | | | | | |
| Comparative | 0.43 | 0.39 | 23.3 | 33.9 | 0.86 | 14.3% | 30.0 |
| Example 2 | | | | | | | |
| Comparative | 0.49 | 0.44 | 20.4 | 38.0 | −0.40 | 2.9% | 35.0 |
| Example 3 | | | | | | | |
| Comparative | 0.47 | 0.52 | 21.1 | — | — | — | 40.0 |
| Example 4 | | | | | | | |
| Example 1 | 0.51 | 0.56 | 15.6 | 29.5 | −2.82 | 26.1% | 15.0 |
| Example 2 | 0.58 | 0.54 | 8.6 | 29.9 | −1.99 | 31.9% | 17.5 |
| Example 3 | 0.58 | 0.54 | 17.3 | 32.9 | −0.15 | 20.7% | 20.0 |
| Example 4 | 0.53 | 0.47 | 5.7 | 30.2 | −0.99 | 23.6% | 17.5 |
| Example 5 | 0.53 | 0.95 | 19.0 | 32.3 | −0.21 | 23.6% | 15.0 |
| Example 6 | 0.53 | 0.58 | 9.4 | 29.9 | −0.88 | 30.7% | 17.5 |
| Example 7 | 0.58 | 0.54 | 17.3 | 31.7 | −0.14 | 20.9% | 20.0 |
| Example 8 | 0.53 | 0.47 | 15.2 | 30.1 | −1.35 | 31.0% | 17.5 |
| Example 9 | 0.81 | 0.58 | 12.4 | 31.1 | −2.42 | 17.5% | 15.0 |
| Example 10 | 0.54 | 0.45 | 18.6 | 31.9 | −0.01 | 18.0% | 20.0 |
| Example 11 | 0.46 | 0.45 | 10.9 | 30.3 | −3.88 | 33.3% | 15.0 |
| Example 12 | 0.92 | 0.22 | 10.9 | 30.6 | −0.98 | 20.3% | 17.5 |
| Example 13 | 0.43 | 0.73 | 18.8 | 32.1 | −1.53 | 15.0% | 20.0 |
| Example 14 | 0.69 | 0.36 | 14.5 | 30.2 | −0.99 | 23.6% | 17.5 |
| Example 15 | 0.54 | 0.45 | 5.6 | 32.8 | −0.52 | 18.0% | 20.0 |
| Example 16 | 0.51 | 0.56 | 9.8 | 29.5 | −2.81 | 25.4% | 15.0 |

The results of Table 2 have demonstrated that the resist compositions used in Examples provide high resolution.

Even in the case of using multiple beams for EB exposure, results similar to those described above were obtained.

The present invention can provide an actinic ray-sensitive or radiation-sensitive resin composition that provides high resolution, an actinic ray-sensitive or radiation-sensitive film formed using the actinic ray-sensitive or radiation-sensitive resin composition, a pattern forming method using the actinic ray-sensitive or radiation-sensitive resin composition, and a method for producing an electronic device.

The present invention has been described in detail and with reference to specific embodiments thereof; however, it would be apparent to those skilled in the art that various changes and modifications can be made therein without departing from the spirit and scope of the present invention.

What is claimed is:

1. An actinic ray-sensitive or radiation-sensitive resin composition comprising:
a resin (A) including an acid-decomposable group and a phenolic hydroxyl group;
a resin (B) which does not include an acid-decomposable group;
an acid generator (C); and
an acid diffusion control agent (D),
wherein the resin (B) includes a repeating unit (b1) having a hydrophilic group and a fluorine atom,
the hydrophilic group and the fluorine atom in the repeating unit (b1) are covalently bonded to a main chain of the resin (B), or are covalently bonded to a side chain which is covalently bonded to the main chain of the resin (B), and
the resin (B) does not include an ammonium salt structure.

2. The actinic ray-sensitive or radiation-sensitive resin composition according to claim 1, wherein a total amount of the acid generator (C) relative to a total solid content of the actinic ray-sensitive or radiation-sensitive resin composition is 0.40 mmol/g or more and 1.50 mmol/g or less.

3. The actinic ray-sensitive or radiation-sensitive resin composition according to claim 1, wherein Qp, which is a value obtained by dividing a total substance amount of the acid diffusion control agent (D) included in the actinic ray-sensitive or radiation-sensitive resin composition by a total substance amount of cations included in the actinic ray-sensitive or radiation-sensitive resin composition, is 0.40 or more and 1.00 or less.

4. The actinic ray-sensitive or radiation-sensitive resin composition according to claim 1, wherein a sum of values obtained by multiplying C log P of each repeating unit included in the resin (B) by a molar fraction of the each repeating unit included in the resin (B) is 0 or less.

5. The actinic ray-sensitive or radiation-sensitive resin composition according to claim 1, wherein a distance Ra between Hansen solubility parameters of the resin (B) and Hansen solubility parameters of air is 35 MPa^{0.5} or less.

6. The actinic ray-sensitive or radiation-sensitive resin composition according to claim 1, wherein a sum of values obtained by multiplying a value obtained by dividing a number of fluorine atoms in each repeating unit included in the resin (B) by a number of all atoms included in the resin (B), by a molar fraction of the each repeating unit included in the resin (B) is 10 mol % or more.

7. The actinic ray-sensitive or radiation-sensitive resin composition according to claim 1, wherein W_{B}/Qp, which is a value obtained by dividing a mass-based content ratio W_{B} of the resin (B) included in the actinic ray-sensitive or radiation-sensitive resin composition by Qp, which is a value obtained by dividing a total substance amount of the acid diffusion control agent (D) included in the actinic ray-sensitive or radiation-sensitive resin composition by a total substance amount of cations included in the actinic ray-sensitive or radiation-sensitive resin composition, is less than 20 mass %.

8. The actinic ray-sensitive or radiation-sensitive resin composition according to claim 1, wherein the repeating unit (b1) is a repeating unit represented by a formula (T1) below: 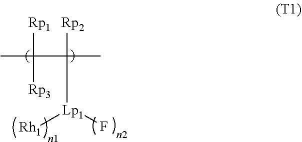
in the formula (T1), Rp₁ to Rp₃ each independently represent a hydrogen atom, an alkyl group, a cycloalkyl group, a halogen atom, a cyano group, or an alkoxycarbonyl group;
Lp₁ represents a linking group;
Rh₁ represents a hydrophilic group;
n1 and n2 each independently represent an integer of 1 or more;
when a plurality of Rh₁ are present, the plurality of Rh₁ may be the same or different; and
two selected from the group consisting of Rp₁ to Rp₃ and Lp₁ may be bonded together to form a ring.

9. The actinic ray-sensitive or radiation-sensitive resin composition according to claim 8, wherein the repeating unit represented by the formula (T1) is a repeating unit represented by any one of formulas (T2) to (T4) below: 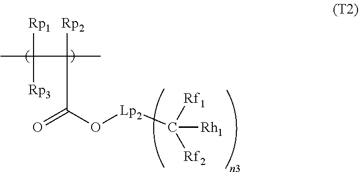
in the formula (T2), Rp₁ to Rp₃ and Rh₁ respectively have the same meanings as Rp₁ to Rp₃ and Rh₁ in the formula (T1);
Lp₂ represents a linking group which is at least one selected from the group consisting of an alkylene group, a cycloalkylene group, and an arylene group;
Rf₁ and Rf₂ each independently represent a fluorine atom or a fluorinated alkyl group;
n3 represents an integer of 1 or more;
when a plurality of Rh₁, Rf₁, and Rf₂ are present, the plurality of Rh₁, Rf₁, and Rf₂ may be individually the same or different; and
two selected from the group consisting of Rp₁ to Rp₃ may be bonded together to form a ring, 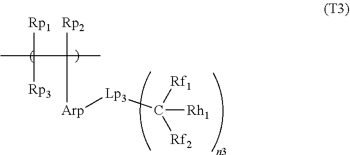
in the formula (T3), Rp₁ to Rp₃ and Rh₁ respectively have the same meanings as Rp₁ to Rp₃ and Rh₁ in the formula (T1);
Arp represents an arylene group;
Lp₃ represents a linking group which is at least one selected from the group consisting of an alkylene group, a cycloalkylene group, —O—, and —CO—, or a single bond;
Rf₁ and Rf₂ each independently represent a fluorine atom or a fluorinated alkyl group;
n3 represents an integer of 1 or more;
when a plurality of Rh₁, Rf₁, and Rf₂ are present, the plurality of Rh₁, Rf₁, and Rf₂ may be individually the same or different; and
two selected from the group consisting of Rp₁ to Rp_{3,} Arp, and Lp₃ may be bonded together to form a ring, 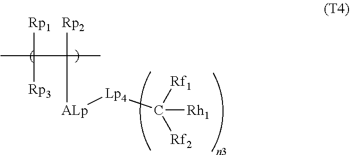
in the formula (T4), Rp₁ to Rp₃ and Rh₁ respectively have the same meanings as Rp₁ to Rp₃ and Rh₁ in the formula (T1);
ALp represents a linking group which is at least one selected from the group consisting of an alkylene group and a cycloalkylene group;
Lp₄ represents a linking group which is at least one selected from the group consisting of an arylene group, —O—, and —CO—, or a single bond;
Rf₁ and Rf₂ each independently represent a fluorine atom or a fluorinated alkyl group;
n3 represents an integer of 1 or more;
when a plurality of Rh₁, Rf₁, and Rf₂ are present, the plurality of Rh₁, Rf₁, and Rf₂ may be individually the same or different; and
two selected from the group consisting of Rp₁ to Rp₃, ALp, and Lp₄ may be bonded together to form a ring.

10. The actinic ray-sensitive or radiation-sensitive resin composition according to claim 1, wherein the resin (A) includes at least one repeating unit selected from the group consisting of a repeating unit represented by a formula (S1) below and a repeating unit represented by a formula (S2) below: 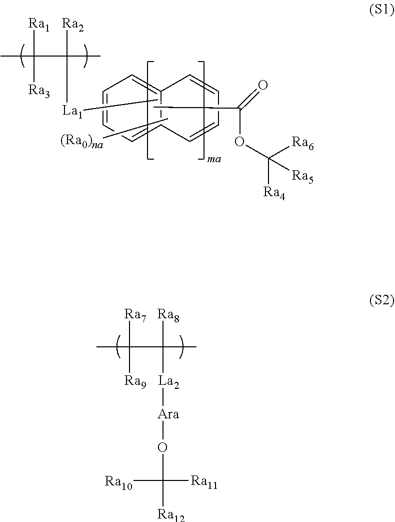
in the formula (S1), Ra₁ to Ra₃ each independently represent a hydrogen atom, an alkyl group, a cycloalkyl group, a halogen atom, a cyano group, or an alkoxycarbonyl group;
La₁ represents a single bond or a divalent linking group;
Ra₄ to Ra₆ each independently represent a hydrogen atom, an alkyl group, a cycloalkyl group, an aryl group, an aromatic heterocyclic group, an aralkyl group, or an alkenyl group;
two selected from the group consisting of Ra₄ to Ra₆ may be bonded together to form a ring;
Ra₀ represents a substituent; when a plurality of Ra₀ are present, the plurality of Ra₀ may be the same or different;
two selected from the group consisting of Ra₁ to Ra₃, La₁, and Ra₀ may be bonded together to form a ring;
na represents an integer of 0 to 4; and
ma represents an integer of 0 to 2,
in the formula (S2), Ra₇ to Ra₉ each independently represent a hydrogen atom, an alkyl group, a cycloalkyl group, a halogen atom, a cyano group, or an alkoxycarbonyl group;
La₂ represents a single bond or a divalent linking group;
Ara represents an aromatic ring group;
Ra₁₀ to Ra₁₂ each independently represent a hydrogen atom, an alkyl group, a cycloalkyl group, an aryl group, an aromatic heterocyclic group, an aralkyl group, an alkoxy group, a cycloalkyloxy group, or an alkenyl group;
at least two selected from the group consisting of Ra₁₀ to Ra₁₂ may be bonded together to form a ring; and
at least one selected from the group consisting of Ra₉ to Ra₁₂ may be bonded to Ara.

11. The actinic ray-sensitive or radiation-sensitive resin composition according to claim 1, wherein the resin (A) includes a repeating unit represented by a formula (S3) below: 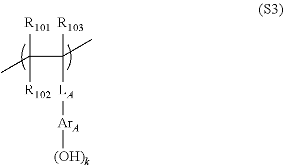
in the formula (S3), R₁₀₁, R₁₀₂, and R₁₀₃ each independently represent a hydrogen atom, an alkyl group, a cycloalkyl group, a halogen atom, a cyano group, or an alkoxycarbonyl group; R₁₀₂ may be bonded to Ar_{A} to form a ring and, in this case, R₁₀₂ represents a single bond or an alkylene group;
L_{A} represents a single bond or a divalent linking group;
Ar_{A} represents an aromatic ring group; and
k represents an integer of 1 to 5.

12. An actinic ray-sensitive or radiation-sensitive film formed by using the actinic ray-sensitive or radiation-sensitive resin composition according to claim 1.

13. A pattern forming method comprising:
resist film formation of using the actinic ray-sensitive or radiation-sensitive resin composition according to claim 1 to form a resist film;
exposure of exposing the resist film; and
development of developing the exposed resist film using a developer.

14. A method for producing an electronic device, the method comprising the pattern forming method according to claim 13.
